(19) United States
(12) Patent Application Publication
(10) Pub. No.: US 2016/0005849 A1
(43) Pub. Date: Jan. 7, 2016

(54) METHOD AND APPARATUS FOR 3D CONCURRENT MULTIPLE PARALLEL 2D QUANTUM WELLS

(71) Applicant: QUALCOMM Incorporated, San Diego, CA (US)

(72) Inventors: Xia LI, San Diego, CA (US); Bin YANG, San Diego, CA (US); Ming CAI, San Diego, CA (US)

(21) Appl. No.: 14/321,539

(22) Filed: Jul. 1, 2014

(51) Int. Cl. H01L 29/778; H01L 29/66; H01L 21/02; H01L 29/201; H01L 29/205; H01L 21/762; H01L 29/78; H01L 29/20

(52) U.S. Cl. CPC H01L 29/7789; H01L 29/7851; H01L 29/66462; H01L 29/66795; H01L 29/20; H01L 29/201; H01L 29/205; H01L 21/76224; H01L 21/02546; H01L 21/02543

(57) ABSTRACT

An inner fin of a high bandgap material is on a substrate, having two vertical faces, and is surrounded by a carrier redistribution fin of a low bandgap material. The inner fin and the carrier redistribution fin have two vertical interfaces. The carrier redistribution fin has a thickness and a bandgap relative to the bandgap of the inner fin that establishes, along the two vertical interfaces, an equilibrium of a corresponding two two-dimensional electron gasses.

### FIELD OF DISCLOSURE

The present application is generally related to transistor structure and, more particularly, to FinFET devices.

### BACKGROUND

When field effect transistor (FET) devices are very small, quantum effects that may be overlooked in larger FET devices may become significant. One result, if conventional large FET design rules are maintained, is that leakage currents may be unacceptable. One known FET technology directed to overcome or avoid this problem is the “quantum well” or “QW” FET. The QW FET is structured to employ, rather than suffer cost from, the quantum effects. Conventional QW FETs include a channel structure formed of a semiconductor channel layer extending between a source and a drain, having a particular bandgap and confined between adjacent members having a different bandgap. Selectively applying an electric field to the semiconductor channel layer selectively allows and eliminates a two-dimensional sheet of free electrons at the interface. The two-dimensional sheet can be referred to as a “two-dimensional electron gas sheet” or “2DEG.”

### SUMMARY

The following summary touches on certain examples in accordance with one or more exemplary embodiments. It is not a defining overview of all exemplary embodiments or contemplated aspects. It is not intended to prioritize or even identify key elements of all aspects, or to limit the scope of any embodiment or any aspect of any embodiment.

Various example multiple quantum well FinFET are disclosed. One or more examples of the disclosed multiple quantum well FinFETs can include a fin base, which may be supported on a substrate, and the fin base may be formed of a first material having a high bandgap, and can include an inner fin, which may be on the fin base, and the inner fin may be formed of a second material that has a high bandgap, and may have a first vertical face and a second vertical face, the second vertical face being spaced a fin thickness from and parallel to the first vertical face, and a carrier redistribution fin, formed of a third material having a low bandgap, and the carrier redistribution fin may surround the inner fin. In one or more examples of the disclosed multiple quantum well FinFETs, the carrier redistribution fin and the first vertical face have a first vertical planar interface, and the carrier redistribution fin and the second vertical face have a second vertical planar interface, and the second material may have a doping, the first material may be reverse doped relative to the doping of the second material, and the third material may have a low doping or may be undoped.

In one or more examples according to disclosed multiple quantum well FinFETs, doping of the first material can be P-type, doping of the second material can be N-type. In an aspect, the first material can include P-doped InAlAs, P-doped AlAs, or P-doped GaAs. In one or more examples, the second material can include InAlAs, AlAs, or GaAs. In one or more examples, the third material can include undoped InGaAs, undoped InGaAsP, low N-doped InGaAs, or low N-doped InGaAsP. Also in one or more examples, a high-K dielectric film can be provided, and the high-K dielectric film may surround an area of the carrier redistribution fin.

One or more other examples of disclosed multiple quantum well FinFETs can include a fin base, which may be supported on a substrate, and the fin base may be formed of a first material, and the first material can have a high bandgap, and can further include a fin, wherein the fin may be on the fin base, the fin may comprise an interleaved stack of 2R strips, R being an integer, wherein the interleaved stack of 2R strips can include R low bandgap strips and R high bandgap strips, wherein the R low bandgap strips and the R high bandgap strips may be arranged in an alternating stacking order. In one or more examples, each of the R low bandgap strips may an upper surface and a lower surface, wherein upper surface forms an upper low bandgap—high bandgap planar interface with a bottom surface of a corresponding one of the R high bandgap strips, and the lower surface forms a lower low bandgap—high bandgap planar interface with a top surface of the fin base or with a top surface of a corresponding another of the R high bandgap strips.

One or more example methods of fabricating a multiple quantum well device are disclosed. Processes in one or more examples of one or more methods can include epitaxial growing a first high bandgap layer on a substrate, epitaxial growing a second high bandgap layer on the first high bandgap layer, patterning a fin from the second high bandgap layer on the first high bandgap layer, having a fin base, wherein the fin base comprises a portion of the first high bandgap layer, forming a shallow trench isolation oxide surrounding the fin base, epitaxial growing a low bandgap layer to cover a surface of the fin forming a high-K dielectric film over a surface of the low bandgap layer, and forming a conducting gate, wherein the conducting gate is formed over a gate region of the high-K dielectric film.

Processes in one or more examples of one or more methods can include epitaxial growing, on a substrate, a high bandgap reverse dopant film, and forming a stacked multiple quantum well fin on the high bandgap reverse dopant film. In processes in one or more examples of one or more methods, example operations in forming the stacked multiple quantum well fin on the high bandgap reverse dopant film can include epitaxial growing a low bandgap undoped layer, epitaxial growing, on the low bandgap undoped layer, a high bandgap N-doped layer, repeating the epitaxial growing a low bandgap undoped layer, and the epitaxial growing a high bandgap N-doped layer R times to form a stack of 2R layers, stack of R layers comprising, in an interleaved alternating order, R low bandgap undoped layers and R high bandgap N-doped layers, and patterning, from the stack of 2R layers, the stacked multiple quantum well fin. In processes in one or more examples of one or more methods, example operations can include forming, around the stacked multiple quantum well fin, a silicon trench isolation oxide, depositing, over the stacked multiple quantum well fin, a dielectric layer, and forming, over a gate region of the dielectric layer, an HK/metal gate.

### BRIEF DESCRIPTION OF THE DRAWINGS

The accompanying drawings are presented to aid in the description of embodiments of the invention and are provided solely for illustration of the embodiments and not limitation thereof.

FIG. 1A is a perspective view, showing certain internal structure by hidden lines, of one multiple parallel two-dimensional (2D) electron gas (EG) QW FET device, in an inner-outer fin aspect according to various exemplary embodiments.

FIG. 1B is a sectional view of the FIG. 1A example multiple parallel 2DEG QW FET device, from the cut plane 1-1.

FIG. 1C is a sectional view of the FIG. 1A example multiple parallel 2DEG QW FET device, in the ON state, from the FIG. 1B cut plane 2-2.

FIG. 1D is a sectional view of the FIG. 1B example multiple parallel 2DEG QW

FET device, from the FIG. 1B cut plane 3-3.

FIG. 2 is a sectional view of an example of one variation, using portions of the FIG. 1A example multiple parallel 2DEG QW FET device, in one multiple QW layer inner-outer fin aspect according to one alternative embodiment, if viewed from the FIG. 1B cut plane 2-2.

FIG. 3 is a sectional view of an example of another variation, using portions of the FIG. 1A example multiple parallel 2DEG QW FET device, providing multiple 2DEGs in another inner-outer fin aspect according to another alternative embodiment, if viewed from the FIG. 1B cut plane 2-2.

FIG. 4A is a perspective view, showing certain internal structure by hidden lines, of one multiple parallel stacked two-dimensional (2D) electron gas (EG) QW FET device, in a stacked multilayer fin aspect according to various exemplary embodiments.

FIG. 4B is a sectional view of the FIG. 4A example multiple parallel stacked 2DEG QW FET device, from the cut plane 3-3.

FIG. 4C is a sectional view of the FIG. 4A example multiple parallel stacked 2DEG QW FET device, in the ON state, from the FIG. 4B cut plane 4-4.

FIG. 5 is a sectional view of an example of another variation, using portions of the FIG. 4A-4C example multiple parallel stacked 2DEG QW FET device, having an outer inner-outer fin aspect providing additional multiple 2DEGs according to one alternative embodiment, if viewed from the FIG. 4B cut plane 4-4.

FIGS. 6A-6J show a snapshot sequence of example in-process structures, formed in one process of fabricating a multiple parallel 2DEG QW FET device according to various exemplary embodiments.

FIG. 7 is a simplified flow chart of example operations in one process of fabricating a multiple parallel 2DEG QW FET device according to various exemplary embodiments.

FIGS. 8A-8E show a snapshot sequence of example in-process structures, formed in one process of fabricating a multiple parallel stacked 2DEG QW FET device according to various exemplary embodiments.

FIG. 9 is a simplified flow chart of example operations in one process of fabricating a multiple parallel stacked 2DEG QW FET device according to various exemplary embodiments.

FIG. 10 shows a functional schematic of one example system of communication and computing devices having combinations of multiple parallel 2D QW channel structure FinFET devices in accordance with one or more exemplary embodiments.

### DETAILED DESCRIPTION

Aspects of the invention are disclosed in the following description and related drawings directed to specific embodiments of the invention. Alternate embodiments may be devised without departing from the scope of the invention. Additionally, well-known elements of the invention will not be described in detail or will be omitted so as not to obscure the relevant details of the invention.

The word “exemplary” is used herein to mean “serving as an example, instance, or illustration.” Any embodiment described herein as “exemplary” is not necessarily to be construed as preferred or advantageous over other embodiments. Likewise, the term “embodiments of the invention” does not require that all embodiments of the invention include the discussed feature, advantage or mode of operation.

The terminology used herein is for describing particular examples illustrating various embodiments, and is not intended to be limiting of embodiments of the invention. As used herein, the singular forms “a”, “an” and “the” are intended to include the plural forms as well, unless the context clearly indicates otherwise. It will be understood that the terms “comprises”, “comprising,” “includes” and/or “including”, when used herein, specify the presence of stated features, integers, steps, operations, elements, and/or components, but do not preclude the presence or addition of one or more other features, integers, steps, operations, elements, components, and/or groups thereof

Further, many embodiments are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, these sequences of actions described herein can be embodied entirely within any form of computer readable storage medium having stored therein a corresponding set of computer instructions that upon execution would cause an associated processor to perform the functionality described herein. Thus, the various aspects of the invention may be embodied in a number of different forms, all of which have been contemplated to be within the scope of the claimed subject matter. In addition, for each of the embodiments described herein, the corresponding form of any such embodiments may be described herein as, for example, “logic configured to” perform the described action.

In an aspect, one 2D-EG QW FET device according to one exemplary embodiment includes an inner fin, of a high bandgap (HBG) material (hereinafter “HBG inner fin”), formed on an HBG fin base. In an aspect, the HBG inner fin may be formed of an n-doped HBG material, for example, n-doped AlGaAs, n-doped AlAs, or n-doped GaAs. In a related aspect, the HBG fin base may be formed of a reverse doped (relative to the HBG inner fin) HBG material, for example a p-doped AlGaAs, p-doped AlAs, or p-doped GaAs. The HBG fin base may be, for example, within a shallow trench isolation (STI) region above a substrate. The HBG inner fin may have two parallel, vertical faces having a fin height and spaced apart by a fin width. The HBG inner fin may extend a fin length along the HBG fin base. Viewed along the fin length, one end of the HBG inner fin may be assigned as a source region and the other, opposite end may be assigned as a drain region. The source region and the drain region are termed “regions” because, in an aspect, the actual source and drain may be respective ends of a channel structure formed on the HBG inner fin, as described in further detail below.

A region of the HBG inner fin between the source region and the drain region may be designated as the channel region. In as aspect, a hollow fin of a low band-gap (LBG) material, labeled for consistent reference in this description as a “carrier redistribution fin” or “CRD fin,” covers the channel region of the HBG inner fin. The CRD fin may, in an aspect, be formed of an undoped low bandgap material, for example, undoped InGaAs or undoped InGaAsP. The CRD fin can have a cross-section comparable to an inverted “U,” with inner planar surfaces that are against, and interface the vertical faces of the HBG inner fin and, at the top, a ceiling that is against, and interfaces the top of the HBG inner fin. Covering at least a portion of the outer surface of the CRD fin can be a high-K/HBG dielectric film. The high-K/HBG dielectric film can have a cross-section comparable to an inverted “U”, with the inner surface conforming to the outer surface of the inverted U form of the CRD fin. A conducting gate can cover at a designated gate region of the high-K/HBG dielectric film. In an aspect, the conducting gate can be a metal gate, or an HK/metal gate. In an aspect, the conducting gate can be connected to a switchable voltage source.

The above-described arrangement of the CRD fin on the HBG inner fin can provide three planes of interface between the inner surface of the CRD fin and the outer surface of the HBG inner fin. Two of the three planes of interface are formed by planar surfaces of the CRD fin against the respective vertical faces of the HBG inner fin. The third plane of interface is between an inner ceiling, i.e., the inside top of the inverted U, of the CRD fin and the top of the HBG inner fin.

In an aspect, the respective dimensions of the materials of the CRD fin and the HBG inner fin may be selected such that a QW forms within the CRD fin at each of these three planar interfaces. In other words, one QW is in the CRD fin in a planar region proximal to its interface with one of the vertical faces of the HBG inner fin. Another QW is in the CRD fin in a planar region proximal to its planar surface interfacing the opposite vertical face of the HBG inner fin. The third QW is proximal to a planar region of the CRD fin proximal to its horizontal planar interface with the top of the HBG inner fin.

In a “normally on” depletion mode aspect, the respective materials and dimensions of the materials of the CRD fin, the HBG inner fin and the containment fin may be selected such that, at least over given range of ambient temperature, a 2DEG (2D electron gas) forms within each of the three QWs—without application of an external electric field.

In a further depletion mode aspect, the respective materials and dimensions of the CRD fin, the HBG inner fin and the containment fin may be selected such that application of a depletion voltage (or control voltage) to the gate creates an electric field that redistributes all three of the 2DEGs, thereby switching the device to an OFF state. When the control voltage is removed, e.g., switched to ground reference voltage, the CRD fin redistributes charge, e.g., electrons, to an equilibrium state providing, in three QWs, the three 2DEGs, i.e., switches the device to an ON state.

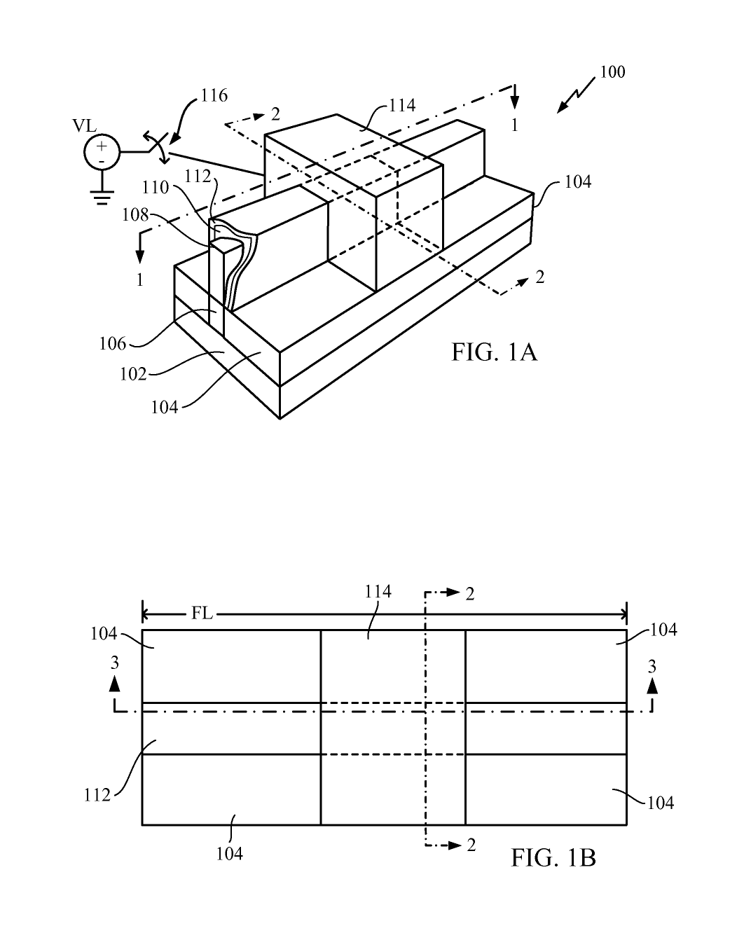

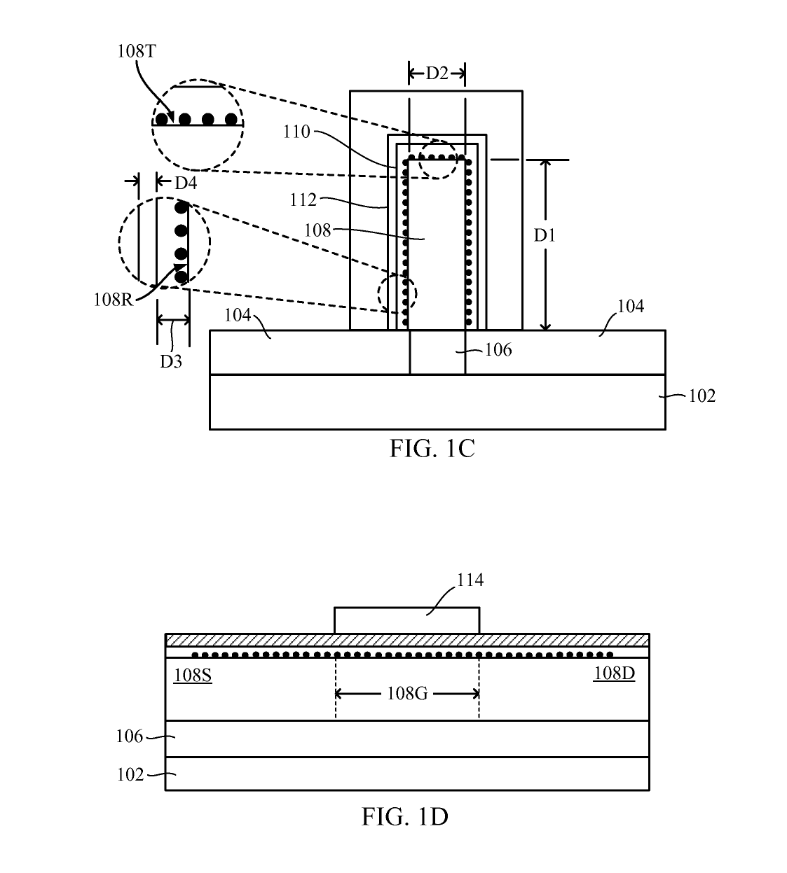

FIG. 1A is a perspective view, showing certain internal structure by hidden lines, of one multiple parallel two-dimensional electron gas (2DEG) QW FET device 100 according to various exemplary embodiments. For brevity, the “multiple parallel 2DEG QW FET device 100” will be referred to alternatively as “MP2DEG device” 100. Referring to FIG. 1A, the MP2DEG device 100 may include a substrate 102 supporting shallow trench isolation (STI) regions 104 on opposite sides of an HBG fin base 106. In an aspect, the HBG fin base 106 may be formed of an undoped or reverse doped AlGaAs, AlAs, or comparable material. On the HBG fin base 106 may be an HBG inner fin 108. The HBG inner fin 108 may be formed, for example, of AlGaAs AlAs or GaAs, with n-type doping. Example details are further shown in the FIG. 1B top view of the MP2DEG device 100, and in the additional views described in reference to FIG. 1C from the FIG. 1A cut plane 2-2 and 1D from the FIG. 1A cut plane 1-1.

It will be understood that, except where expressly stated otherwise in this disclosure, the term “shallow trench isolation” (and its abbreviated form “STI”) refer to structure and function, without limitation as to the process forming the structure. For example, “shallow trench isolation” and “STI” do not necessarily imply etching a trench (not shown in the figures) and filling that trench with a body to be isolated.

Referring to FIGS. 1A and 1B, the HBG inner fin 108 may have an inner fin first vertical face 108R and another vertical face spaced from it by a fin width D1. It will be understood that “vertical,” in the context of describing the HBG inner fin 108 and relating structure, means a direction normal to the substrate 102. The HBG inner fin 108 may project a fin height D2 to an inner fin top surface 108T. Illustrative example values for D1 and D2 may include, for example, approximately 20 nm (nanometers) and approximately 10 nm, respectively. It will be understood that the values of 20 nm and 10 nm are only examples, and are not intended to limit the scope of any of the exemplary embodiments or aspects of the same.

FIG. 1C is a cross sectional view of the MP2DEG device 100 as seen from the FIG. 1B projection plane 2-2. Cut plane 2-2, first shown on FIG. 1A, also passes through the MP2DEG device 100 as seen from the FIG. 1C. Referring to FIG. 1C, the HBG fin base 106 and HBG inner fin 108 can extend for a fin length labeled “FL.”

FIG. 1D is a cross-sectional view of the MP2DEG device 100, as seen from the FIG. 1B cut plane 3-3. Referring to FIG. 1D, the HBG inner fin 108 may extend a length (shown by not separately labeled” from a source region 108S to a drain region 108D. In an aspect, the “source region” 108S may mean an area, as shown, at one end along the length of the HBG inner fin 108, and not necessarily an entirety of a structure functioning a “source.” Likewise, the “drain region” 108D may mean another area, for example, at an opposite end along the length of the HBG inner fin 108, and not necessarily an entirety of a structure functioning as a “drain.” Continuing to refer to FIG. 1D, a region of the HBG inner fin 108 extending from the source region 108S to the drain region 108D may be a channel region (not separately numbered). A region of the HBG inner fin 108 between the source region 108S and the drain region 108D can be designated a “gate region” 108G.

Referring to FIGS. 1A and 1B, the channel region of the HBG inner fin 108 has three planar surfaces, namely, the inner fin vertical face labeled 108R, which may be termed as “first vertical face,” the opposite vertical face (shown but not separately labeled) and the inner fin top surface 108T.

In an aspect, a carrier redistribution (CRD) fin 110 (hereinafter “CRD fin 110”) may be disposed on and conform to the outer surface of the HBG inner fin 108. The CRD fin 110 may be formed of an undoped low bandgap material, for example, undoped InGaAs or InGaAsP. In an alternative aspect, the CRD fin 110 may be formed of a lightly doped low bandgap material, for example, lightly N-doped InGaAs or lightly N-doped InGaAsP. In an aspect, the CRD fin 110 can have a uniform thickness D3. It will be understood that “uniform” can have an application-specific tolerance that persons of ordinary skill in the art, having possession of the present disclosure, can identify, e.g., using simulation tools known to such persons, without undue experimentation. As previously described, in an aspect, the channel region of the HBG inner fin 108 can be configured with three planar surfaces, i.e., the inner fin first vertical face 108R, the inner fin second vertical face (shown but not separately numbered), and the inner fin top surface 108T. The CRD fin 110 therefore establishes three significant LBG-HBG planar interfaces with the HBG inner fin 108.

Referring to FIGS. 1A-1C, covering an outer surface of the CRD fin 110 may be a high-K dielectric film 112. Assuming the CRD fin 110 is formed of an undoped low bandgap material such as undoped InGaAs or InGaAsP, one example high-K dielectric for the high-K dielectric film 112 may be HfO2. The high-K dielectric film 112 may have a thickness D4. The numerical value of D4 can be application-specific. Values of D4 can be determined by persons of ordinary skill in the art having possession of the present disclosure, e.g., using simulation tools known to such persons, without undue experimentation. A metal gate 114, shown connected to a switchable voltage source VL, e.g., a word line (not shown in the figures) may be configured to contact the high-K dielectric film 112, for example, over the above-described gated channel section 108G of the channel region. In an aspect, the metal gate 114 may be connected via an ON-OFF switch 116 to the switchable voltage source VL. The ON-OFF switch 116 may represent, for example, enabling logic of a word line decoder (not shown in the figures).

As previously described, the CRD fin 110 can be formed of an undoped low bandgap material such as undoped InGaAs or InGaAsP. As also described, the HBG inner fin 108 can be a high bandgap N-doped material, for example, n-doped AlGaAs or AlAs or comparable material. Therefore, each of the three described planar LBG-HBG interfaces is a III-V interface. In an aspect, the MP2DEG device 100 may be configured as a depletion mode device, i.e., “normally on” device, to exploit the III-V interfaces. The depletion mode configuration can include selecting described device parameters, such as one or more of the dimensions D1-D3 and/or respective materials forming the CRD fin 110 and the HBG inner fin 108. These device parameters can be selected by persons of ordinary skill possessing this disclosure, without undue experimentation, such that, at least over a given operating range, an equilibrium state is established, in which a 2DEG forms in the 2D-QW established at each of the three planar interfaces with the HBG inner fin 108—in response to a ground reference voltage, e.g., switching the ON-OFF switch 116 OFF. Each of the 2DEGs is, effectively, an ON channel. In a related aspect, the device parameters can be selected such that application of a depletion voltage, e.g., the logic voltage VL (i.e., the ON-OFF switch 116 ON), can establish an electric field in the CRD fin 110 that redistributes the three above-described 2DEGs, thereby switching the MP2DEG device 100 to an OFF state. It will be appreciate that switching the voltage back to the ground reference voltage re-establishes the 2DEG, i.e., the ON channel, in each of the 2D-QWs.

In an aspect of the MP2DEG device 100 as described above, the QWs, i.e., device channels are planar regions within the CRD fin 110 that are close to its inner planar surfaces that interface outer planar surfaces of the channel region of the HBG inner fin 108. Since the QWs are under the surface of the CRD fin 110, surface effect and surface scatter effect may be significantly reduced, to a degree removing each as a significant negative factor.

The MP2DEG device 100 is not a limitation on the scope of devices that can provide multiple 2DEGs in accordance with the various exemplary embodiments. For example, in an alternative aspect, an electron containment fin can be added between the CRD fin 110 and the high-K dielectric film 112 and, in a further aspect, the thickness of the CRD fin 110 can be varied to a modified CRD fin that can function as a QW.

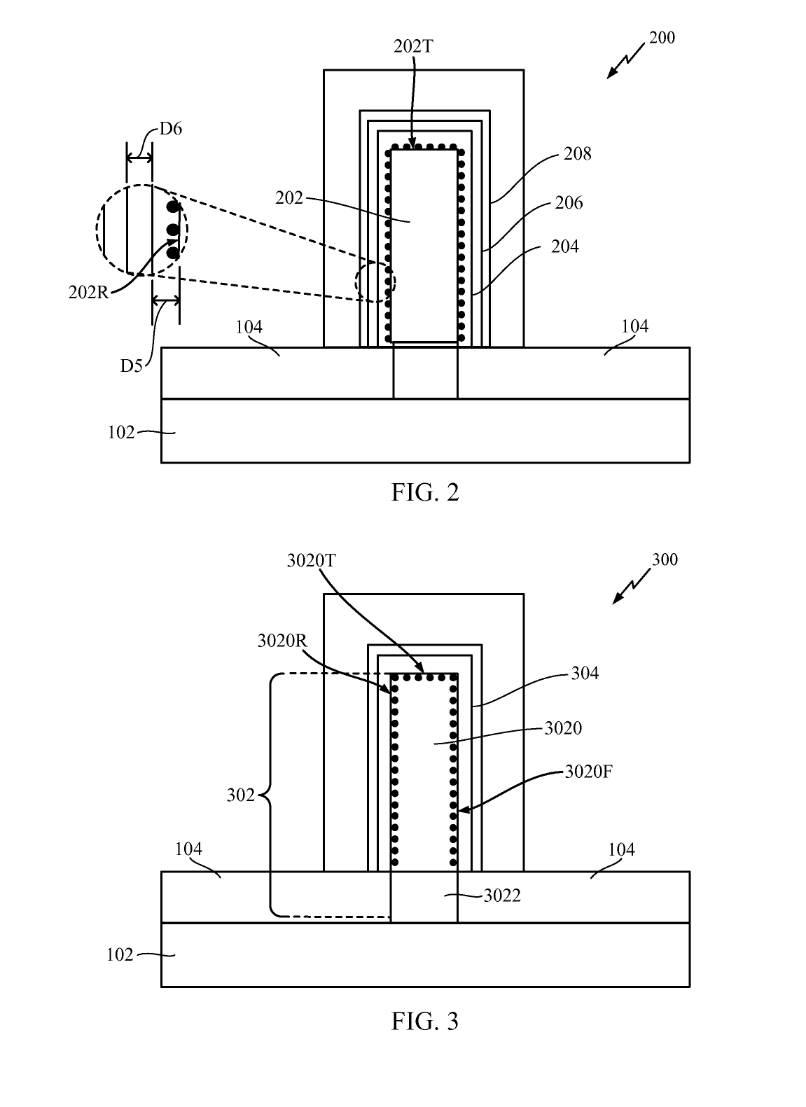

FIG. 2 is a sectional view of a multiple parallel 2DEG QW FET (hereinafter “MPQW device 200”) showing one example according to the above-described aspect. The MPQW device 200 will be described using portions of the FIG. 1A-1D example multiple parallel 2DEG QW FET device 100 to avoid obfuscation with description of new structures not necessarily specific to this particular aspect. Accordingly, like structures may be un-numbered. Further, the FIG. 2 sectional view is the described example MPQW device 200 as would be seen from the FIG. 1A cut plane 2-2, with the FIG. 1A-D structure modified as described herein. It will be understood that description referring to portions of the FIG. 1A-1D example multiple parallel 2DEG QW FET device 100 is not intended to limit the scope of any exemplary embodiment to using such portions.

Referring to FIG. 2, the MPQW device 200 includes an HBG inner fin 202 that may be identical to the FIG. 1A HBG inner fin 108. The HBG inner fin 202 may be supported on a structure (shown but not separately numbered) that may be the FIG. 1A HBG fin base 106. The HBG inner fin 202 may have a first vertical face 202R, a second vertical face (shown, but not separately numbered) and a top face 202T.

Disposed on the HBG inner fin 202 may be a variation of the above-described CRD fin 110. In an aspect, in place of the CRD fin 110 may be a QW fin 204 that is surrounded, in turn, by a containment fin 206.

Disposed on and substantially covering the containment fin 206 may be a high-K film 208 that, for example, may be formed as the high-K dielectric film 112 of the FIG. 1A-1D MP2DEG device 100. A metal gate (shown but not separately numbered), connected to a switchable voltage source (not shown), may be configured to contact the high-K film 208. The metal gate may be formed, for example, as the metal gate 114 of the FIG. 1A-1D MP2DEG device 100.

In the example MP2DEG device 100 and MPQW device 200, the device channels (i.e., QWs) are within planar regions of an LBG hollow fin (e.g., the CRD fin 110) that surrounds an HBG inner fin (e.g., the HBG inner fin 108). In example devices according to another alternative aspect, concurrent, multiple parallel QWs may be provided in an inner fin formed of an undoped LBG material, in regions proximal to its outer planar surfaces interfacing with, for example, a surrounding HBG outer fin.

FIG. 3 is a sectional view of an example multiple parallel 2DEG inner fin QW FET device 300, hereinafter “MP2DEG-IF device 300”) according to the above described aspect. The MP2DEG-IF device 300 will be described using portions of the FIG. 1A-1C example multiple parallel 2DEG QW FET device 100. Description using portions of the FIG. 1A-1D example multiple parallel 2DEG QW FET device 100 is to avoid obfuscation with description of new structures not necessarily specific to this particular aspect. Accordingly, like structures are not numbered. Further, the FIG. 3 sectional view is the described example as would be seen from the FIG. 1A cut plane 2-2, with the FIG. 1A-1D structure modified as described in reference to FIG. 3. It will be understood, however, that description referring to portions of the FIG. 1A-1D example multiple parallel 2DEG QW FET device 100 is not intended to limit the scope of any exemplary embodiment to using such portions.

Referring to FIG. 3, the MP2DEG-IF device 300 includes an inner fin 302, and the inner fin 302 can have an upper portion 3020 and a lower portion 3022. It will be understood that the labels “upper portion” and “lower portion” are not intended to limit the upper portion 3020 and a lower portion 3022 to being constituents of a common structure. The lower portion 3022 may be an n-doped HBG material, such as n-doped AlGaAs or AlAs. The upper portion 3020 may be an LBG undoped material such as InGaAs or InGaAsP. The upper portion 3020 will hereinafter be alternatively referenced as the “LBG inner fin 3020.” Persons of ordinary skill in the art, comparing FIG. 3 with FIGS. 1A-1C, may note that the lower portion 3022 of the inner fin 302 is not necessarily reverse doped.

The LBG inner fin 3020 may have a first vertical face 3020R, a second vertical face 3020F parallel the first vertical face 3020R and a top face 3020T. Disposed on the LBG inner fin 3020 may be an HBG fin 304, which may be a hollow fin of an HBG, doped material such as, for example, n-doped AlGaAs or AlAs. The HBG fin 304 may have a uniform thickness D8. It will be understood that “uniform” can mean within an application-specific range or tolerance. It will also be understood that the range or tolerance can be determined by persons of ordinary skill having possession of the present disclosure, without undue experimentation. A top portion (shown but not separately numbered) of the HBG fin 304 may have an inner planar surface (shown but not separately numbered) against the top face 3020T of the LBG inner fin 3020. One vertical portion (shown but not separately numbered) of the HBG fin 304 may have an inner face (shown but not separately numbered) against the first vertical face 3020L of the LBG inner fin 3020. Another vertical portion (shown but not separately numbered) of the HBG fin 304 may have an inner face (shown but not separately numbered) against the second vertical face 3020R.

Disposed on and substantially covering the HBG fin 304 may a high-K fin (shown but not separately numbered) that, for example, may be formed as the high-K dielectric film 112 of the FIG. 1A-1C MP2DEG device 100. A metal gate (shown but not separately numbered), connected to a switchable voltage source (not shown), may be configured to contact the high-K fin. The metal gate may be formed, for example, as the metal gate 114 of the FIG. 1A-1C MP2DEG device 100.

The above-described example multiple parallel 2DEG FinFET devices, e.g., the MP2DEG device 100, the MPQW device 200 and the MP2DEG-IF device 300, each provide, among other features and benefits, concurrent, multiple parallel QWs that selectively carry concurrent, multiple parallel 2DEGs. The particular implementations of the above-described MP2DEG device 100, MPQW device 200 and MP2DEG-IF device 300 each provide, for example, a concurrent two laterally spaced parallel QWs along with one horizontal (along the top of the inner fin) QW.

Example multiple parallel 2DEG QW FinFET devices according to various alternative embodiments can also provide concurrent multiple stacked QWs. In various aspects, a significantly quantity of concurrent multiple stacked QWs may be provided.

In an aspect, an HBG fin base can be provided on a substrate. Disposed on the HBG fin base strip may be a stack of 2R strips, comprising R LBG strips and R HBG strips. The R LBG strips may be formed, for example, of InGaAs or InGaAsP. The InGaAs or InGaAsP forming the R LBG strips can be either undoped or lightly N-type doped. The R HBG strips may be formed, for example, of AlGaAs, AlAs or GaAs, doped with an N-type dopant. As described in further detail in later sections of this disclosure, the R LBG strips and R HBG strips can be configured, in accordance with various exemplary embodiments, to establish QWs in the LBG strips, at their respective interfaces with the HBG strips.

In an aspect, the R LBG strips and R HBG strips are stacked in an alternating order, providing an interleaving of R LBG strips with R HBG strips. The alternating pattern may begin with a first LBG strip overlaying the HBG base strip, then a first HBG strip overlaying the first LBG strip. Next, a second LBG strip overlays the first HBG strip, followed by a second HBG strip overlaying the second LBG strip. The alternating pattern repeats to establish the above-described vertical interleaving of R LBG strips and R HBG strips. The interleaved pattern establishes, for each of the R LBG strips, an upper planar interface between it and its overlaying HBG strip, and a lower planar interface between it and its underlying HBG strip (or, for the first LBG strip, the underlying HBG base strip). Therefore, from the perspective of each of the LBG strips, each of the above-described upper interfaces and lower interfaces is an LBG-HBG interface.

As described previously in this disclosure, the R LBG strips may be formed, for example, of InGaAs or InGaAsP, which may be undoped or lightly N-type doped. The R HBG strips may be formed, for example, of AlGaAs, AlAs or GaAs, doped with an N-type dopant. In an aspect, the respective thicknesses of the LBG strip and the HBG strip, and the difference in their respective bandgaps can be set to establish within each of the LBG strips an upper quantum well and a lower quantum well. The upper quantum well is proximal to the upper LBG-HBG interface with its overlaying HBG strip, and the lower quantum well is proximal to the lower LBG-HBG interface between it and its underlying HBG strip (or, for the first LBG strip, the underlying HBG base strip).

In a further aspect, the respective thickness of the LBG strips and HBG strips and the difference in their respective bandgap can be set such that, in the absence of an external electric field, within each LBG strip a 2DEG (two-dimensional electron gas) forms within its upper quantum well, and another 2DEG forms within its lower quantum well. The absence of an external electric can be established by, for example, placing a ground reference voltage on a conducting gate, described later in further detail. Each of the upper 2DEG and lower 2DEG is a conducting, i.e., “ON” channel. Among features provided by the alternating stacking of LBG strips and HBG strips according to exemplary embodiments is that 2R parallel 2DEGs are formed.

In an aspect, the respective thicknesses of the LBG strip and the HBG strip, and the difference in their respective bandgaps can be set to establish within each of the LBG strips an upper quantum well and a lower quantum well. The upper quantum well is proximal to the upper LBG-HBG interface with its overlaying HBG strip, and the lower quantum well is proximal to the lower LBG-HBG interface between it and its underlying HBG strip (or, for the first LBG strip, the underlying HBG base strip).

In a further aspect, since one of the above-described upper 2DEGs and one of the described lower 2DEGs forms within each of the LBG strips, each of the LBG strips operates as a channel strip. Each of the HBG strips, in contrast, operates as a barrier strip. Accordingly, the described interleaved pattern establishes an interleaving of R channel strips and R barrier strips. Each of the R channel strips supports, proximal to its upper interface with an overlaying barrier strip, an upper QW. Each of the N-channel strips supports, proximal to its lower interface with an underlying barrier strip (or, for the first LBG strip, the underlying HBG base strip), a lower QW.

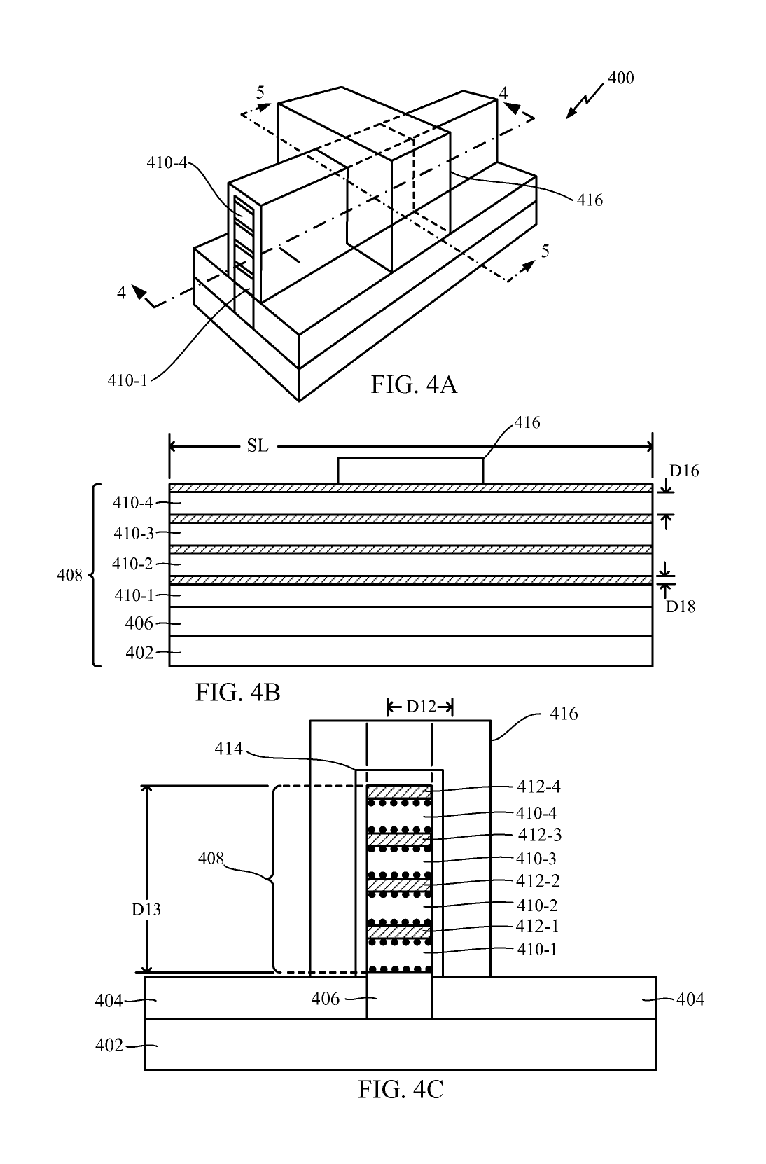

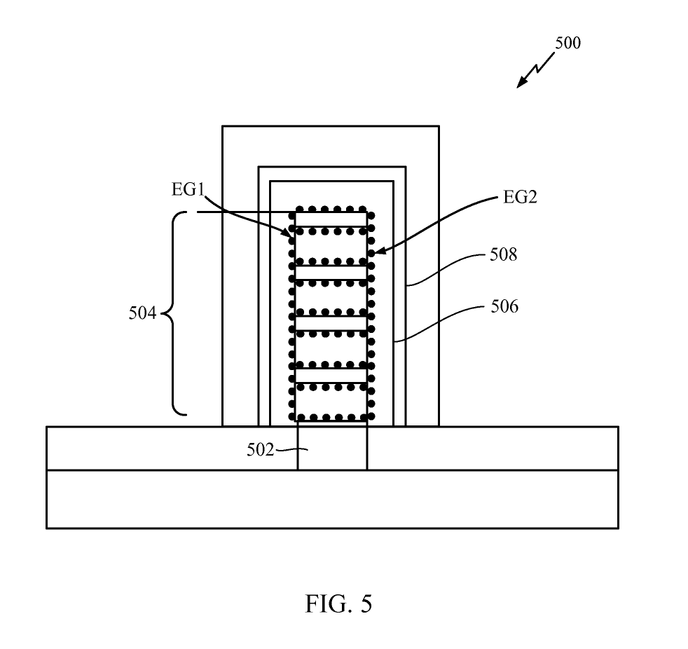

FIG. 4A is a perspective view, showing certain internal structure by hidden lines of one example of one stacked multiple 2DEG QW FinFET device 400 (hereinafter “SM-2DEG device 400”) according to one or more exemplary embodiments. FIG. 4B shows a cross-sectional view of the SM-2DEG device 400 seen from the FIG. 4A cut plane 4-4, and FIG. 4C is a cross-sectional view, seen from the FIG. 4A cut plane 5-5.

Referring to FIG. 4A, the SM-2DEG device 400 may include a substrate 402 supporting shallow trench isolation (STI) regions 404 and a fin base 406. In an aspect, the fin base 406 is formed of a high bandgap material, and will therefore be referred to as the “HBG fin base” 406. In an aspect, the HBG fin base 406 may be formed, for example, of reverse doped AlGaAs, reverse doped AlAs, undoped AlGaAs or undoped AlAs. In an aspect, “reverse doped” can be P-type doping.

Referring to FIGS. 4B and 4C, on the HBG fin base 406 may be a multilayer, stacked multiple QW fin (hereinafter “SM QW fin 408”). The SM QW fin 408 may extend a length SL and may have a thickness D12. Illustrative example values for D12 may include, for example, approximately 10 nm (nanometers) and may span at least, for example, approximately 10 to approximately 20 nm. It will be understood that the value of approximate 110 nm, and range spanning at least approximately 10 to approximately 20 nm are only examples, and are not intended to limit the scope of any of the exemplary embodiments or aspects of the same. The SM QW fin 408 may have a height D13. Illustrative example values for D13 may include, for example, any value within a range spanning from at least approximately 10 to approximately 20 nm. It will be understood that the range spanning at least approximately 10 to approximately 20 nm are is only one examples, and is intended to limit the scope of any of the exemplary embodiments or aspects of the same.

According to various exemplary embodiments, the SM QW fin 408 may comprise an interleaved pattern of a first LBG strip 410-1, a first HBG strip 412-1, a second LBG strip 410-2, a second HBG strip 412-2, a third LBG strip 410-3, a third HBG strip 412-3, a fourth LBG strip 410-4 and a fourth HBG strip 412-4. It will be understood that four is an arbitrarily selected number that is not intended as any limitation on the quantity of strips (or layers from which the strips can be patterned) that may be used in practices according to the exemplary embodiments. For convenience in description, the first LBG strip 410-1, second LBG strip 410-2, third LBG strip 410-3 and fourth LBG strip 410-4 will be collectively referenced as “the LBG strips 410” (a label not separately shown on FIGS. 4A-4C). Likewise, the first HBG strip 412-1, second HBG strip 412-2, third HBG strip 412-3 and fourth HBG strip 412-4 will be collectively referenced as “the HBG strips 412” (a label not separately shown on FIGS. 4A-4C). The LBG strips 410 can have a thickness D16 and the HBG strips 412 can have a thickness D18. Illustrative example values for D16 may include, for example, any value within a range spanning at least from approximately 2 nm to approximately 4 nm, and illustrative example values for D18 may include, for example, any value within a range spanning at least from approximately 2 nm to approximately 3 nm. It will be understood that these example ranges are only for purpose of illustration, and are not intended to limit the scope of any of the exemplary embodiments or aspects of the same.

In an aspect, the R LBG strips 410 may be formed, for example, of undoped InGaAs, undoped InGaAsP, lightly N-doped InGaAs, or lightly N-doped InGaAsP. The R HBG strips 412 may be formed, for example, of N-doped AlGaAs, N-doped AlAs or N-doped GaAs.

Referring to FIGS. 4A-4C, each of the LBG strips 410 and each of the HBG strips 412 may have, when projected on a plane normal to the cut-plane 5-5, an outer perimeter and dimension identical to, or comparable to, the outer shape and dimension of the SM QW fin 408. The example SM QW fin 408 is formed by the first LBG strip 410-1 overlaying the HBG fin base 406, then the first HBG strip 412-1 overlaying the first LBG strip 410-1. Next, the second LBG strip 410-2 overlays the first HBG strip 412-1, followed by the second HBG strip 412-2 overlaying the second LBG strip 410-2. This pattern can repeat, with the third LBG strip 410-3 overlaying the second HBG strip 412-2, followed by the third HBG strip 412-3 overlaying the third LBG strip 410-3. Finally, the fourth LBG strip 410-4 overlays the third HBG strip 412-3, and the fourth HBG strip 412-4 overlays the fourth LBG strip 410-4. Each of the R LBG strips 410 has an upper surface and a lower surface (visible in FIGS. 4A-4C, but not separately labeled). Likewise, each of the R HBG strips 412 has an upper surface and a lower surface (visible in FIGS. 4A-4C, but not separately labeled). A result, from the perspective of each of the LBG strips 210, its upper surface forms an upper low bandgap—high bandgap planar interface with the bottom surface of a corresponding one of the R high bandgap strips 412, and its lower surface forms a lower low bandgap—high bandgap planar interface with the top surface of the fin base 406 or with the top surface of a corresponding another of the R HBG strips 412.

The above-described FIG. 4A-4C interleaving pattern establishes, for each of the four LBG strips 410, an upper planar interface between it and its overlaying HBG strip 412, and a lower planar interface between it and its underlying HBG strip 412 (or, for the first LBG strip 410-1, the underlying HBG fin base 406). Therefore, from the perspective of each of the LBG strips 410, the upper planar interface with its overlaying HBG strip 412 is an upper LBG-HBG interface, and the lower planar interface with its underlying HBG strip 412 is a lower LBG-HBG interface.

In an aspect, the respective thickness of the LBG strips 410 and HBG strips 412, and the difference in their respective bandgap, may be set to establish within each of the LBG strips 410 an upper QW (quantum well) and a lower QW. The upper QW may be proximal to the upper LBG-HBG planar interface between it and its overlaying HBG strip 412. The lower QW may be proximal to the lower LBG-HBG planar interface between it and its underlying HBG strip 412 (or, for the first LBG slice 410-1, the underlying HBG base support). In the example shown in FIGS. 4A-4C, R is four and, accordingly, a stack of eight parallel QWs can be provided. In a general sense, configuring R LBG strips and R HBG strips in the interleaved stacking pattern according to various exemplary embodiments can provide a stack of 2R parallel horizontal QWs.

In an aspect, a high-K dielectric film 414 may surround the SM QW fin 408. The high-K dielectric film 414 may be identical to the high-K dielectric film 112 of FIG. 1C. A conducting gate 416 surrounds a given gate region (shown but not separately labeled) of high-K dielectric film 414.

Referring to FIG. 4C, the example R of four establishes a stack of eight QWs. Therefore, in a general sense, configuring R LBG strips and R HBG strips in the interleaved stacking pattern according to various exemplary embodiments can provide, within the SM QW fin 408, a stack of 2R QWs. Application of a ground reference voltage on the conducting gate 416 can produce an ON state in which a 2DEG forms within each of the 2R QWs, such as shown by the SM-2DEG device 400 in an ON state, More particularly, for each LGB strip 410, an upper 2DEG can form in the upper QW and a lower 2DEG can form in the lower QW. Because the QWs are within the LBG strips 410, and the LBG strips 410 are undoped, the 2DEGs are high mobility without substantial surface effect or surface scattering effect. It will be appreciated that a result can be 2R ON channels of high mobility carriers. When a depletion voltage is placed on the conducting gate 416, the LGB strips 410 can distribute the carriers, i.e., remove the upper 2DEG and lower 2DEG from LBG strip 410. As will be appreciated, when the ground reference voltage is again applied to the conducting gate 416, the described structure re-establishes the upper 2DEG and lower 2DEG in each of the LBG strips 210.

As previously described, the SM-2DEG device 400 having R equal to four is only an example. As illustration, the SM-2DEG device 400 can be modified by removing 410-3, 412-3, 410-4 and 412-4, to obtain one alternative SM-2DEG device (not separately shown) having R equal to two.

The above-described examples include MP2DEG device 100, MPQW device 200 and MP2DEG-IF device 300, showing aspects providing multiple parallel QWs, each proximal to a respective one of multiple parallel vertical LBG-HBG interface planes. The above-described examples also include the SM-2DEG device 400, providing a stack of 2RQWs, each proximal to a respective one of a stack of 2R parallel, horizontal (i.e., normal to the fin height direction) LBG-HBG interface planes. In accordance with various exemplary embodiments, various fin structures can be configured to provide multiple parallel vertical LBG-HBG interface planes, in combination with a stack of 2R horizontal LBG-HBG interface planes. The multiple parallel vertical LBG-HBG interface planes, and concurrent stack of 2R parallel horizontal LBG-HBG interface planes can establish, in accordance with depletion mode aspects, an equilibrium state of multiple parallel vertical 2DEGs concurrent with a stack of multiple parallel horizontal 2DEGs. The equilibrium state can be associated, as described, with placing a ground reference voltage on the conducting gate.

FIG. 5 is a sectional view of one example multiple vertical 2DEG/stacked multiple horizontal 2DEG FinFET device 500 (hereinafter “MV/SMH-2DEG device” 500) in accordance with various exemplary embodiments. In an aspect, the MV/SMH-2DEG device 500 can provide two laterally spaced parallel vertical 2DEGs concurrent with a stack of 2R parallel horizontal 2DEGs.

The MV/SMH-2DEG device 500 will be described using portions of the FIG. 2 MPQW device 200, combined with portions of the FIG. 4A-4C SM-2DEG device 400. Like structures are not necessarily numbered in FIG. 5. Description according to the MV/SMH-2DEG device 500 implemented as such is to avoid obfuscation with description of new structures. It will be understood, however, that description of the MV/SMH-2DEG device 500 implemented using portions of the MPQW device 200 and SM-2DEG device 400 is not intended to limit the scope of any exemplary embodiments.

Referring to FIG. 5, on an HBG base support 502 may be a multilayer, stacked QW inner fin 504 (hereinafter “MS QW inner fin 504”). The MS QW inner fin 504 may be according to the SM QW fin 408 described in reference to FIG. 4A-4C. Accordingly, the MS QW inner fin 504 can establish the stack of eight QWs, and the associated equilibrium stack of eight 2DEGs (shown in FIG. 5, but not separately numbered) established by the SM QW fin 408.

Surrounding the MS QW inner fin 504 may be a carrier redistribution (CRD) fin 506, which may be a hollow fin of an LBG, undoped material such as, for example, undoped InGaAs or InGaAsP. The CRD fin 506 may be structured similar to the CRD fin 110 of FIGS. 1A-1D. Disposed on and substantially covering the CRD fin 506 may be a high-K dielectric layer 508 that, for example, may be formed as the high-K dielectric film 112 of the FIG. 1A-1C MP2DEG device 100. Accordingly, the CRD fin 506 and MS QW inner fin 504 can establish the two vertical plane 2DEGs (shown in FIG. 5 as “EG1” and “EG2”) and the top horizontal plane 2DEG (shown in FIG. 5, but not separately numbered) established in the CRD fin 110 of the FIG. 1A-1C MP2DEG device 100. Referring to FIG. 5, a metal gate (shown but not separately numbered), connected to a switchable voltage source (not shown), may be configured to contact a gate region (shown but not separately numbered) of the high-K dielectric layer 508. The metal gate may be formed, for example, as the metal gate 114 of the FIG. 1A-1C MP2DEG device 100.

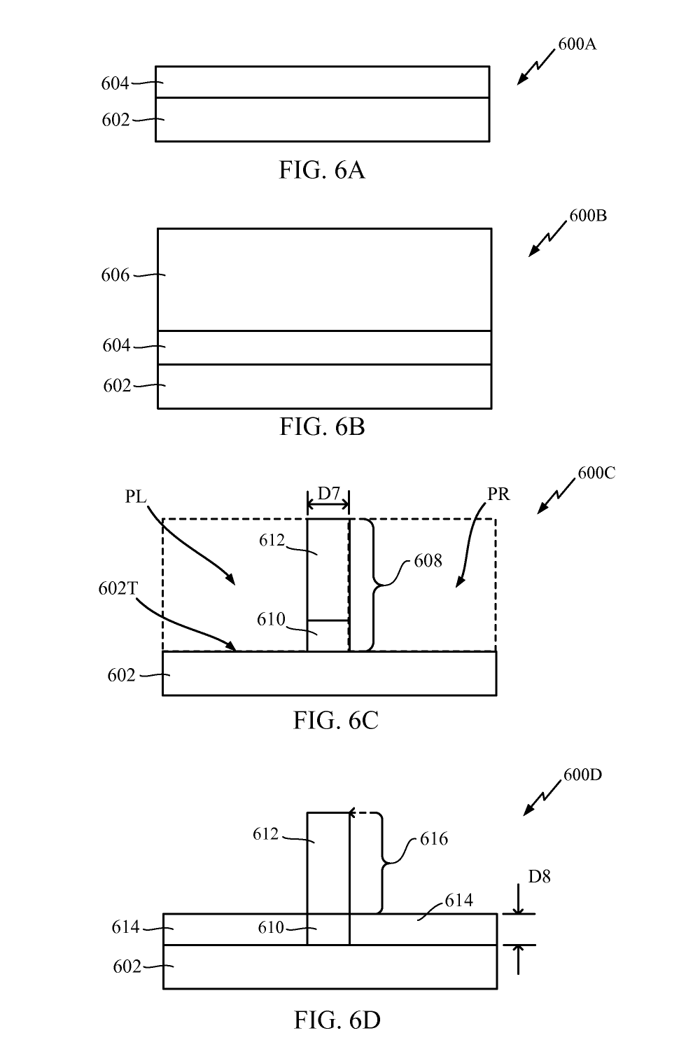

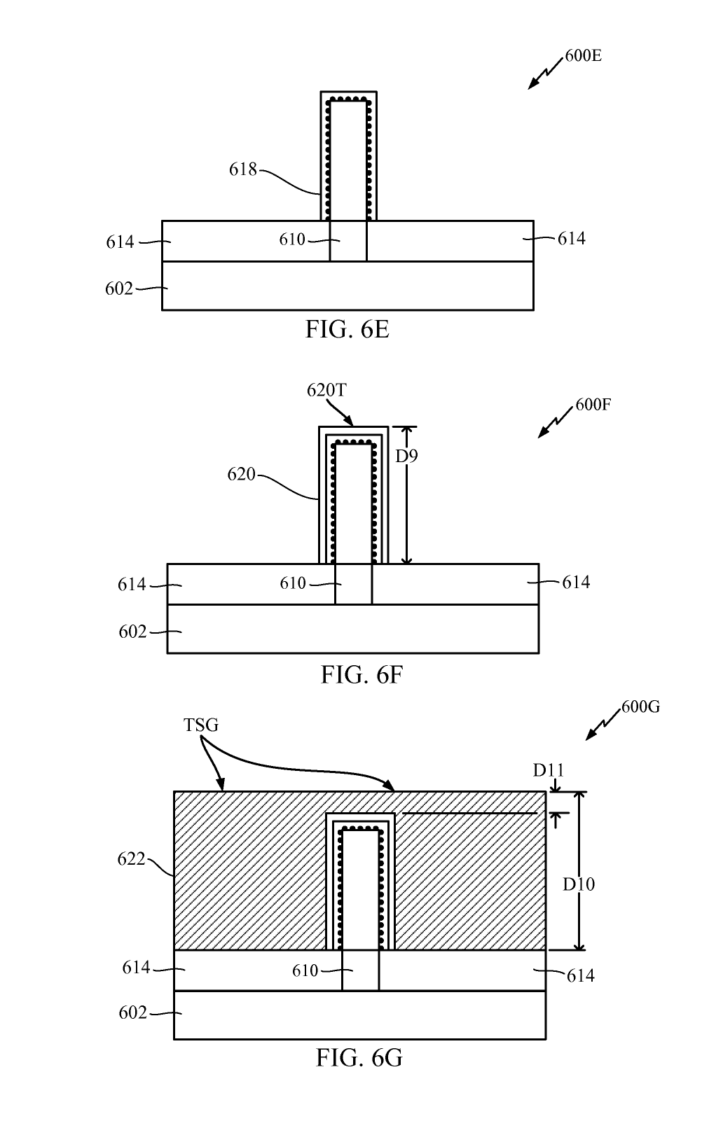

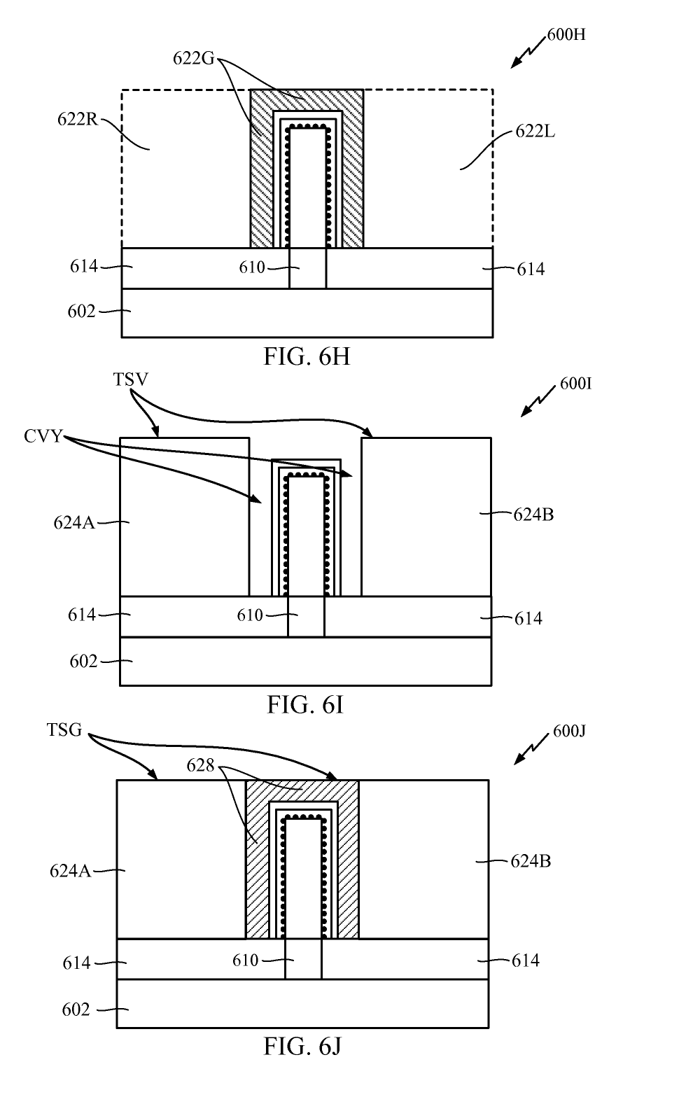

FIGS. 6A-6J show a snapshot sequence of example in-process structures in one process of fabricating one example multiple parallel 2DEG QW FET device according to various exemplary embodiments. The FIG. 6A-6J in-process structures can be in an example process for forming a multiple parallel 2DEG QW FET device having structure such as described in reference to FIGS. 1A-1D. The in-process structures of FIGS. 6A-6J are shown from a projection comparable to the FIG. 1A cut plane 2-2. It can be assumed that the in-process structures of FIGS. 6A-6G have a length (not shown in FIGS. 6A-6J) that extends into and out from the plane of the figures. For convenience, the length can be assumed to be the length FL shown in FIG. 1B.

Referring to FIG. 6A, one example starting structure 600A can include a high bandgap undoped, or reverse doped semiconductor film 604 on a substrate 602. The term “reverse doped,” in this context, means opposite the doping of the overlaying layer described in reference to FIG. 6B. The high bandgap undoped, or reverse doped semiconductor film 604 can be, for example, undoped or reverse doped AlGaAs, AlAs, or a comparable material. As will be described in reference to FIG. 6C, subsequent operations can remove all of the high bandgap undoped, or reverse doped semiconductor film 604 except for a portion comparable to the FIG. 1 HBG fin base 106. Therefore, the high bandgap undoped, or reverse doped semiconductor film 604 will be alternatively referred to as the “HBG fin base film” 604.

Next, referring to FIG. 6B, a high bandgap film 606 can be formed, e.g., by epitaxial growing the high bandgap film 606 on a top surface (shown but not separately numbered) of the HBG fin base film 604 to form the in-process structure 600B. Assuming, for purposes of example, the device being formed is as an N-type transistor, the high bandgap film 606 can be AlGaAs, AlAs or GaAs, with n-type doping. As will be described in reference to FIG. 6C, subsequent operations can remove all portions of the high bandgap film 606 except for a portion comparable to the FIG. 1A HBG inner fin 108. The high bandgap film 606 will therefore be referred to as the “N-type HBG inner fin film 606.”

Referring to FIG. 6C, in an aspect, an in-process fin 608 can be patterned from the N-type HBG fin film 606 on the HBG fin base film 604, to obtain the in-process structure 600C. The patterning can form the in-process fin 608 with a thickness D7 comparable to the thickness D shown on FIG. 1C. The patterning can include, for example, placing a hard mask (not shown in the figures) on a top surface (visible, but not separately labeled) of the N-type HBG film 606 and etching the “PR” and “PL” portions of the high HBG fin film 606 and HBG fin base film 604 down to an upper surface 602T of the substrate 602. The portion of the in-process fin 608 contributed by the HBG fin base film 604 can be referred to as an “in-process HBG fin base” 610. The portion of the in-process fin 608 contributed by the N-type HBG fin film 606 can be referred to as an “in-process N-type HBG inner fin” 612. As previously described, it can be assumed that the in-process structure 600C, and therefore the in-process fin 608 extends, on the substrate 602, the length FL shown in FIG. 1B. It can be further assumed that the in-process fin 608 has, at one end (not visible in FIG. 6C) a source region and, at an opposite end, has a drain region, with a designated gate region that interfaces with a gate (not shown in FIG. 6C).

Referring to FIG. 6D, in an aspect, an STI (silicon dioxide trench isolation) layer 614 can be deposited on the upper surface 602T of the substrate 602. The thickness of the STI layer 614, D8, can be approximately the same as the thickness of the HBG fin base 610. Therefore, the portion of the in-process N-type HBG inner fin 612 projecting above the STI layer 614 can be referred to as the “N-type HBG inner fin” 616. The N-type HBG inner fin 616 has a left vertical face 616L, an opposing right vertical face 616R (collectively, “vertical faces”) spaced from the left vertical face by a fin thickness D6, and a fin top surface 616T. Continuing to refer to FIG. 6D, a first portion (shown but not separately numbered) of the STI layer 614, can abut the left side (where “left” means facing FIG. 6D) of the HBG fin base 610. Similarly, a second portion (shown but not separately numbered) of the STI layer 614 can abut the right side of the HBG fin base 610.

Referring to FIG. 6E, a charge redistribution (CRD) fin 618 can be formed on the N-type HBG inner fin 616 to provide the in-process structure 600E. The CRD fin 618 may be formed of, for example, undoped InGaAs or InGaAsP. The CRD fin 618 can cover, and thereby form three interfaces with the outer surface of the N-type HBG inner fin 616. The CRD fin 618 can be formed with a thickness (visible, but not separately labeled on FIG. 6E) comparable to the D4 thickness described in reference to FIG. 1C. Two of the three interfaces are at the vertical faces of the N-type HBG inner fin 616, and the third is at the fin top surface 616T of the N-type HBG inner fin 616. In an aspect, the respective dimensions, e.g., thicknesses, and materials forming the CRD fin 618, the N-type HBG inner fin 616 and the gate structures can be selected to provide, as described in further detail herein, an equilibrium state forming a 2DEG (two-dimensional electron gas) at each of these three interfaces. The CRD fin 618 will therefore be referenced as the “multiple parallel 2DEG CRD fin 618” or “MP/2DEG CRD fin” 618.

Referring to FIG. 6F, a dielectric layer 620 can be formed on outer surfaces of the MP/2DEG CRD fin 618 to form the in-process structure 600F. The dielectric layer 620 can be formed, for example, of normal oxide or high-K dielectric. The dielectric layer 620 can be formed with a thickness (visible, but not separately labeled on FIG. 6F) comparable, for example, to the thickness D5 shown on FIG. 1C. A top surface 620T of the dielectric layer 620 can be spaced a distance D9 above a top surface of the STI layer 614.

Referring to FIG. 6G, a poly dummy gate layer 622 can be deposited, with a height or thickness D10 above a top surface of the STI layer 614. The height or thickness D10 can be determined by the desired height D11 of a top surface “TSG” of the poly dummy gate layer 622 above the top surface (shown on FIG. 6F as 620T) of the dielectric layer 620. The height D11 can determine a corresponding height, or thickness, of a metal gate described in further detail in reference to FIG. 6J. The forming of the poly dummy gate layer 622 can include mechanical processing (MP) (not shown in the figures), and/or chemical processing (CP) (not shown in the figures), collectively referred to as “CMP”, to smooth the top surface TSG. As will be apparent to persons of ordinary skill in the art upon reading this disclosure, CMP smoothing can assist the use of hard masks (not shown in the figures) in the patterning described in reference to FIG. 6H. The CMP can be in accordance with known, conventional CMP techniques and, therefore, further detailed description is omitted.

Referring to FIG. 6H, a poly dummy gate 622G can be patterned from the poly dummy gate layer 622 to form the in-process structure 600H. The patterning can include disposing hard masks on the top surface TSG, and etching the sections 622R and 622L (delineated on FIG. 6H by dotted lines) to leave the poly dummy gate 618G as a remainder.

Referring to FIG. 6I, in an aspect, operations in one example process according to various exemplary embodiments can include depositing an inter-layer dielectric (ILD) oxide layer surrounding the dummy gate 622G, and then removing the dummy gate 622G to obtain the in-process structure 6001. As shown in FIG. 6I, one example ILD oxide layer can be formed as the first ILD oxide layer 624A and the second ILD oxide layer 624B. In the FIG. 6I example, the first ILD oxide layer 624A abuts a left facing outer wall (visible in FIG. 6H, but not separately labeled) of the dummy gate 622G, and the second ILD oxide layer 624B abutting a right facing outer wall (visible in FIG. 6H, but not separately labeled) of the dummy gate 622G. As visible in FIG. 6I, removing the dummy gate 622G leaves a cavity “CVY” between the first ILD oxide layer 624A and the second ILD oxide layer 624B. The cavity CVY exposes a designated gate surface area (not fully visible in FIG. 6I) of the dielectric layer 620 previously in contact with the dummy gate 622G.

In an aspect, included in or associated with forming the ILD oxide layer (e.g., the first ILD oxide layer 624A and second ILD oxide layer 624B), CMP operations (not shown in the figures) can be performed, for example, to obtain a desired smoothness the top surface TSV. The CMP operations smoothing TSV can be in accordance with known, conventional CMP techniques and, therefore, further detailed description is omitted.

Referring to FIG. 6J, in an aspect, operations in a fabrication process according to various exemplary embodiments can include depositing in the cavity 622 a high-K/metal gate 626 or re-deposit a high-K/metal gate 626, as shown by the in-process structure 600G. In an aspect, included in or associated with forming the high-K/metal gate 626, CMP operations (not shown in the figures) can be performed, for example, to obtain a desired smoothness the top surface TSG. CMP operations smoothing the top surface TSG can be in accordance with known, conventional CMP techniques and, therefore, further detailed description is omitted.

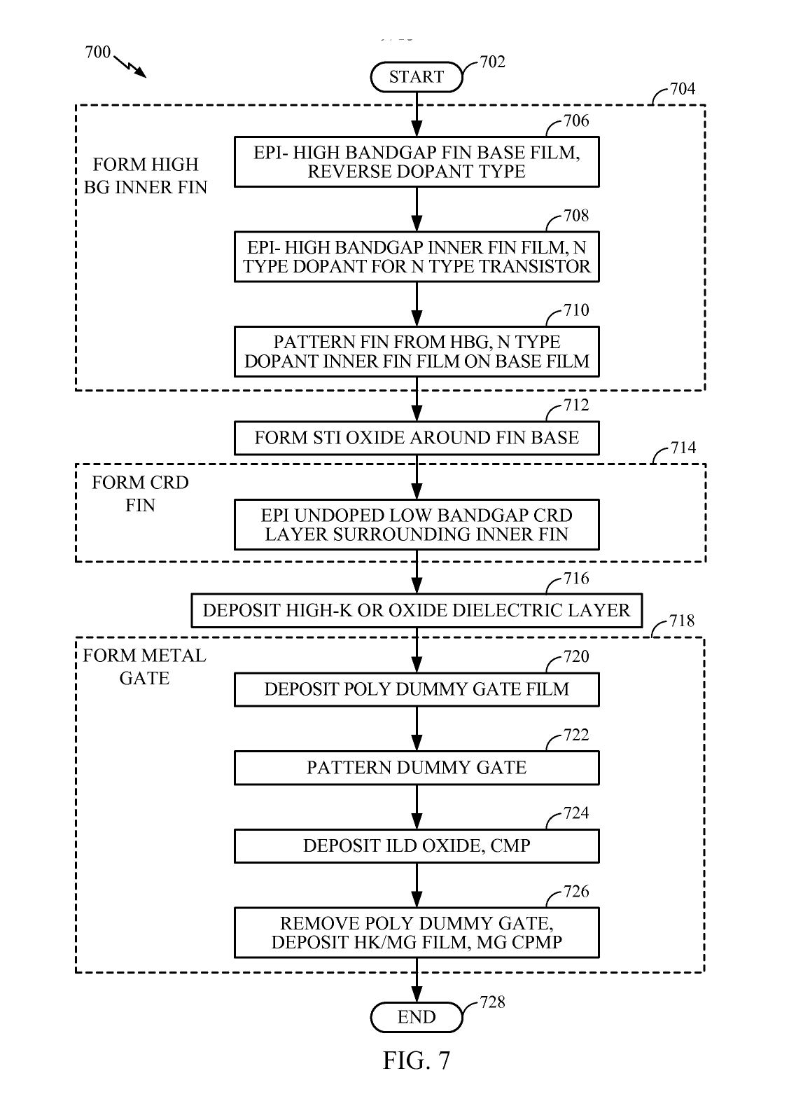

FIG. 7 represents one flow of example operations 700 in one example process of fabricating a multiple parallel 2DEG FinFET device according to various exemplary embodiments. To provide example structures illustrative of certain of the operations 700, it will be assumed the process is for fabricating toward the MP2DEG device 100 of FIGS. 1A-1D. Reference is also made to the in-process structures of FIGS. 6A-6J.

Referring to FIG. 7, example operations 700 can start from an arbitrary start state 702, and then proceed to forming, at 704, a high bandgap inner fin, such as the FIG. 1A-1B HBG inner fin 108 on its HBG fin base 106 on the substrate 102. The forming at 704 can include, at 706, epitaxial growing a high bandgap reverse dopant fin base film on a substrate, for example, referring to FIG. 6A, epitaxial growing on the substrate 602 the HBG fin base film 604. The epitaxial growing at 704 can include not doping, or reverse doping the high bandgap fin base film, as described for the HBG fin base film 604. Assuming the device is an N-type, the forming at 704 can include, at 708, epitaxial growing an N-type doped high bandgap inner fin film on the high bandgap reverse dopant fin base film formed at 706. Referring to FIGS. 6B and 7, one example of the epitaxial growing at 708 can be the described epitaxial growing of the N-type HBG inner fin film 606 on the HBG fin base film 604. Referring to FIG. 7, operations in the forming of the HBG inner fin at 704 can include, at 710, patterning the HBG inner fin from the described overlay formed at 706 of the N-type doped high bandgap inner fin film on the high bandgap reverse dopant fin base film formed at 704. Referring to FIGS. 6C and 7, one example of a patterning at 710 of the HBG inner fin can be the described etching of the N-type HBG inner fin film 606 on the HBG fin base film 604, for forming the in-process fin 608.

Example operations 700 can include, after the forming of the HBG inner fin at 704, a forming, at 712, of an STI oxide around the base or base portion of the HBG inner fin. Referring to FIG. 6D and FIG. 7, one example of a forming at 712 of an STI oxide around the base or base portion of the HBG inner fin formed at 704 can be the described forming of the STI layer 614. For example, the forming at 712 can form the STI oxide with a thickness such as the example D8, which can be approximately the same as the thickness of the high bandgap reverse dopant fin base film formed at 706.

Continuing to refer to FIG. 7, after forming the STI oxide at 712, example operations 700 can include, at 714, forming a carrier redistribution or charge redistribution (CRD) fin surrounding exposed surfaces of the HBG inner fin formed at 704. The CRD fin can be formed of, for example, undoped InGaAs or InGaAsP. Referring to FIG. 6E and FIG. 7, one example of the forming, at 714, of a CRD fin can be the described epitaxial growing of the MP/2DEG CRD fin 618. Example operations 700 can further include, after forming at 714 of the CRD fin, depositing at 716 a dielectric film or layer, e.g., a high-K or normal oxide dielectric film or layer on the CRD fin. Referring to FIG. 6F and FIG. 7, one dielectric film formed at 716 on the CRD fin formed at 714 can be the example dielectric layer 620, which may be high-K or normal oxide dielectric.

Referring to FIG. 7, after depositing the dielectric film at 716, example operations 700 can include, at 718, forming a metal gate. Example operations at 718 in the forming of a metal gate can include depositing, at 720, a poly dummy gate film. Referring to FIGS. 6G and 7, depositing the poly dummy gate layer 622 can be one example of the depositing at 720. Example operations in forming, at 716, a metal gate can further include patterning, at 722, a dummy gate from the poly dummy gate film deposited at 720. Referring to FIG. 6H and FIG. 7, the described patterning of the dummy gate 622G can be one example of the patterning at 722.

Continuing to refer to FIG. 7, operations 700 can include, after patterning the dummy gate at 722, depositing, at 724, an inter-layer dielectric (ILD) oxide surrounding the dummy gate. Referring to FIGS. 6I and 7, the previously described depositing the first oxide layer 624A and the second oxide layer 624B can be one example of the depositing at 724. In an aspect, CMP operations may be associated or included with the depositing at 724 of the ILD oxide. Such CMP operations can be in accordance with known, conventional CMP techniques and, therefore, further detailed description is omitted. After depositing the ILD oxide at 724, operations 700 can include, at 726, removing the poly dummy gate formed at 722 and forming a HK/metal gate in its place. Removing the poly dummy gate at 726 can leave a gate cavity in the ILD oxide, such as the FIG. 6I cavity “CVY”, exposing an outer surface of a gate region of the HBG inner fin formed at 704. Referring to FIG. 6J and FIG. 7, the HK/metal gate 626 can be one example of the high-K/metal gate deposited at 726. In an aspect, associated with or included in the operations at 726 can be one or more CMP operations to smooth top surfaces (e.g., to provide for hard masks), for example, the FIG. 6I top surface TSV and the FIG. 6J top surface TSG.

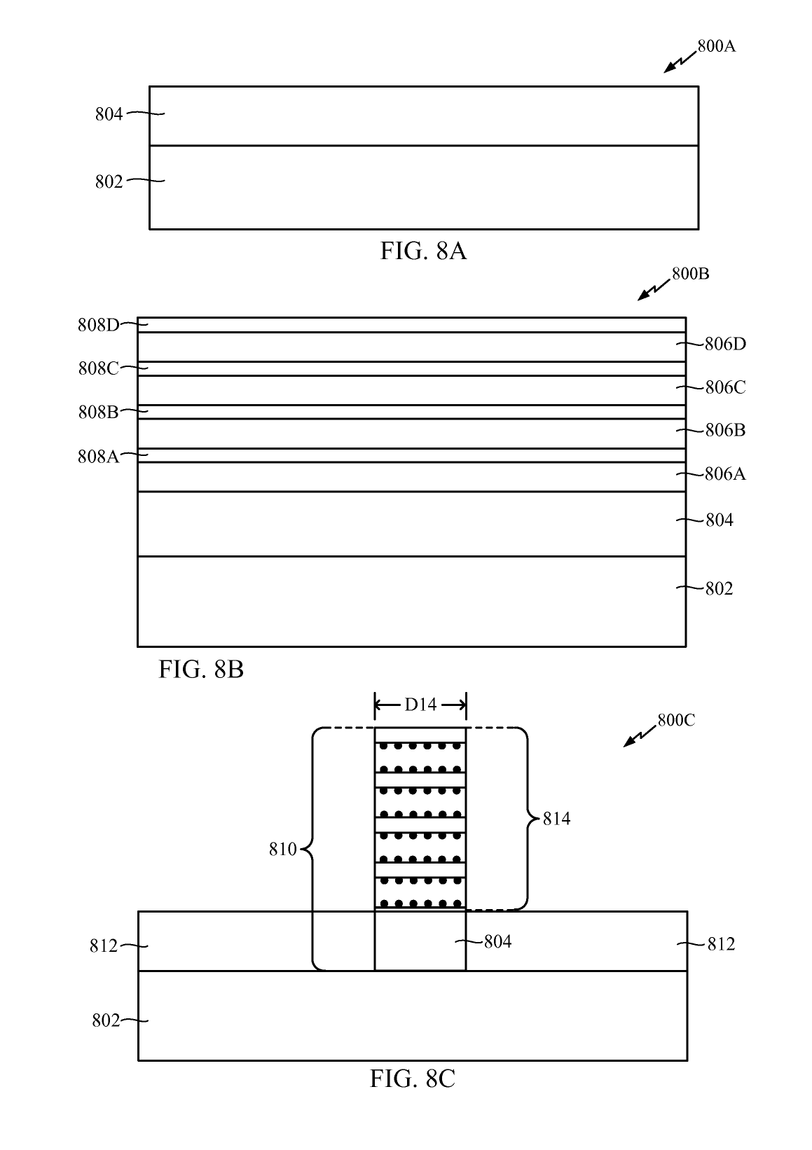

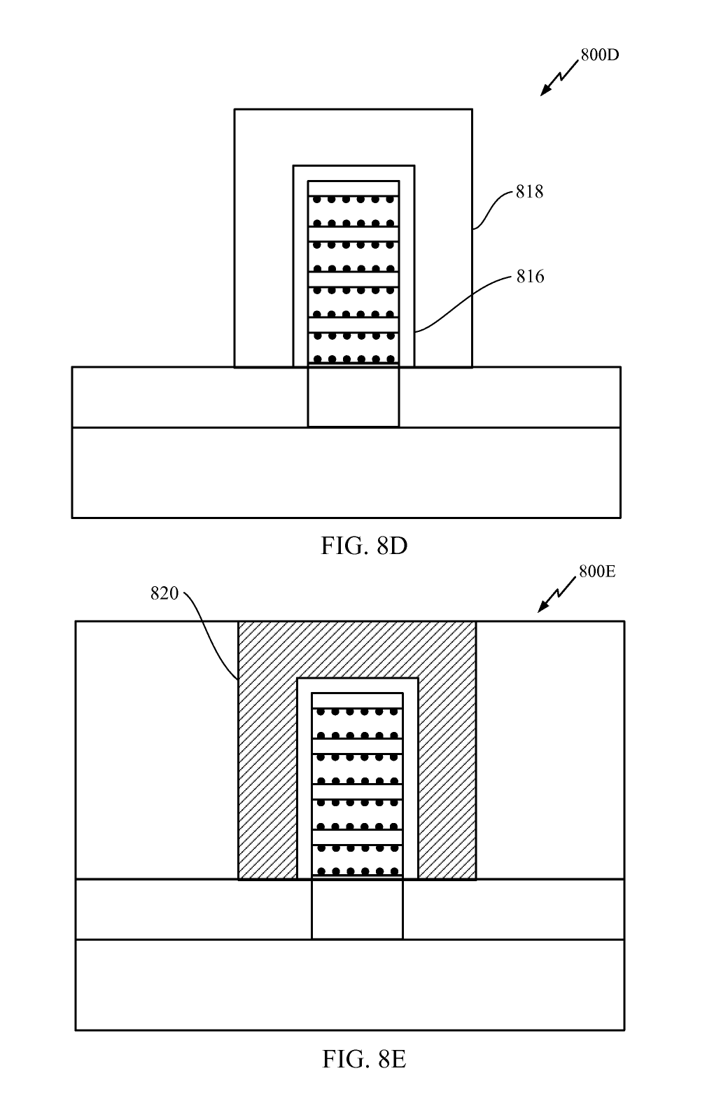

FIGS. 8A-8E show a snapshot sequence of in-process structures formed in one example process of fabricating multiple parallel stacked 2DEG FinFET devices according to various exemplary embodiments. The example process forming the in-process structures of FIGS. 8A-8E can be a process forming a multiple-parallel stacked 2DEG device structured such as the MPS-2DEG device 400 of FIGS. 4A-4C. It will be understood that the in-process structures of FIGS. 8A-8E are shown from a projection comparable to the FIG. 4A cut plane 4-4. It can be assumed that the in-process structures of FIGS. 8A-8E have a length (not shown in FIGS. 8A-8E) extending normal to the plane of the figures, e.g., the length SL shown in FIG. 4B.

Referring to FIG. 8A, one example starting structure 800A can include a high bandgap film 804 epitaxial grown on a substrate 802. The high bandgap film 804 can be reverse doped or undoped semiconductor The term “reverse doped,” in this context, means a doping opposite the doping of the overlaying layer in the next in-process structure 800B described in reference to FIG. 8B. For example, assuming an N-type doping for the next in-process structure 800B, the high bandgap film 804 may be formed of P-doped AlGaAs, P-doped AlAs, undoped AlGaAs or undoped AlAs.

Referring to FIG. 8B, in-process structure 800B can be formed by successive epitaxial growing on the high bandgap reverse doped semiconductor film 804 a stack of 2R layers, comprising R low bandgap (LBG) layers and R high bandgap (HBG) layers arranged in alternating order. The R LBG layers may be formed, for example, of InGaAs or InGaAsP, which can be either undoped or lightly N-type doped. The R HBG layers may be formed, for example, of N-doped AlGaAs, N-doped AlAs or N-doped GaAs.

In the FIG. 8B example, the 2R layers include a first LBG layer 806A epitaxial grown on a top surface (visible but not separately labeled) of the high bandgap reverse doped semiconductor film 804, followed by a first HBA layer 808A epitaxial grown on a top surface (visible but not separately labeled) of the first LBG layer 806A. A second LBG layer 806B can be epitaxial grown on a top surface (visible but not separately labeled) of the first HBG layer 808A. A second HBG layer 808B epitaxial can then be grown on a top surface (visible but not separately labeled) of the second LBG layer 806B. It will be appreciated by persons of ordinary skill upon reading this disclosure that devices according to various exemplary embodiments can be constructed an R of two. If R is two, the successive forming of HBG layers on LBG layers can be completed with the second HBG layer 808B.

Referring to FIG. 8B, assuming R is four, a third LBG layer 806C can be epitaxial grown on a top surface (visible but not separately labeled) of the second HGB layer 808B, followed by a third HBG layer 808C epitaxial grown on a top surface (visible but not separately labeled) of the third LBG layer 806C. The successive forming can end with a fourth LBG layer 806D epitaxial grown on a top surface (visible but not separately labeled) of the third HBG layer 808C, and a fourth HBG layer 808D epitaxial grown on a top surface (visible but not separately labeled) of the fourth LBG layer 806D. For convenience in description, the first LBG layer 806A, second LBG layer 806B, third LBG layer 806C and fourth LBG layer 806D will be collectively referenced as “the LBG layers 806” (a label not separately shown on FIGS. 8A-8E). Likewise, the first HBG layer 808A, second HBG layer 808B, third HBG layer 808C and fourth HBG layer 808D will be collectively referenced as “the HBG layers 808” (a label not separately shown on FIGS. 8A-8E).

Referring to FIG. 8C, in an aspect, in-process structure 800C can be formed by patterning an in-process stacked layer fin 810 from the interleaved stack of R LBG layers 806 and R HBG layers 808, followed by depositing an STI oxide layer 812 on opposing sides of the in-process stacked layer fin 810. The patterning can form the in-process stacked layer fin 410 with a fin thickness D14 comparable to the fin thickness D12 shown on FIG. 4C. The patterning can be substantially as described for forming the in-process fin 608 of FIG. 6C. The depositing the STI oxide layer 812 can be substantially as described for depositing the STI oxide layer 612 of FIG. 6D. The thickness D15 of the STI oxide layer 812 can be approximately the same as, or slightly less than the thickness of the high bandgap reverse doped semiconductor film 804. The portion of the in-process stacked layer fin 810 projecting above the STI oxide layer 812 can be referred to as the “stacked multiple quantum well” (“SM QW”) fin 814.

For convenience in description, the portion of the SM QW fin 814 contributed by the first LBG layer 806A can be referred to as the ‘first LBG strip” (visible in FIG. 8C but not separately numbered). The portions contributed by the second LBG layer 806B, the third LBG layer 806C and the fourth LBG layer 806D can be referred to, respectively, as the “second LBG strip” (visible but not separately numbered), the “third LBG strip” (visible but not separately numbered) and the “fourth LBG strip” (visible but not separately numbered). Similarly, the portion of the MS QW fin contributed by the first HBG layer 808A can be referred to as the ‘first HBG strip” (visible in FIG. 8C but not separately numbered). The portions contributed by the second HBG layer 808B, the third HBG layer 808C and the fourth HBG layer 808D can be referred to, respectively, as the “second HBG strip” (visible but not separately numbered), the “third HBG strip” (visible but not separately numbered) and the “fourth HBG strip” (visible but not separately numbered). The first LBG strip, the second LBG strip, the third LBG strip and the fourth LBG strip can be referred to, collectively, as the “LBG strips of the SM QW fin 814.” The first HBG strip, the second HBG strip, the third HBG strip and the fourth HBG strip can be referred to collectively as the “HBG strips of the SM QW fin 814.”

Substantially as described in reference to FIG. 4A-4C, the interleaving pattern of the LBG strips and the HBG strips of the SM QW fin 814 establishes, in each of the four LBG strips of the MS QW fin 814, an upper QW and a lower QW. The upper QW is established proximal to the upper planar interface between it and its overlaying HBG fin slice. Based on the respective bandgaps of the LBG strips and HBG strips of the SM QW fin 814, a 2DEG can form within each of the upper QWs and within each of the lower QWs. Since the upper QWs and the lower QWs are established within the LBG strips of the MS QW fin 814, which are undoped, the associated 2DEGs are high mobility without substantial surface effect or surface scattering effect.

Referring to FIG. 8D, in an aspect, in-process structure 800D can be formed by depositing a dielectric layer 816, e.g., high-K or normal oxide dielectric layer, on an outer surface of the SM QW fin 814, depositing a dummy gate poly layer (not shown in its entirety), and patterning the dummy gate poly layer to form the dummy gate 818. Depositing the dielectric layer 816 can be substantially as described for the FIG. 6F dielectric layer 620. Operations in depositing a dummy gate poly layer can be substantially as described for forming the FIG. 6G dielectric layer 620. Patterning the dummy gate 818 can be substantially as described for patterning the FIG. 6H dummy gate 622G.

Referring to FIG. 8E, in an aspect, in-process structure 800E can be formed by depositing ILD and CMP and removing the dummy gate 818 and depositing, in its place, an HK/metal gate 820. Operations associated with depositing the HK/metal gate 820 can be substantially as described for forming the FIG. 6J HK/metal gate 624. Referring to FIG. 8E, associated with the HK/metal gate 820, an inter-layer dielectric (ILD) layer may be adjacent the outer vertical faces 820L and 820R, similar to the FIG. 6J first ILD oxide layer 624A and second ILD oxide layer 624B.

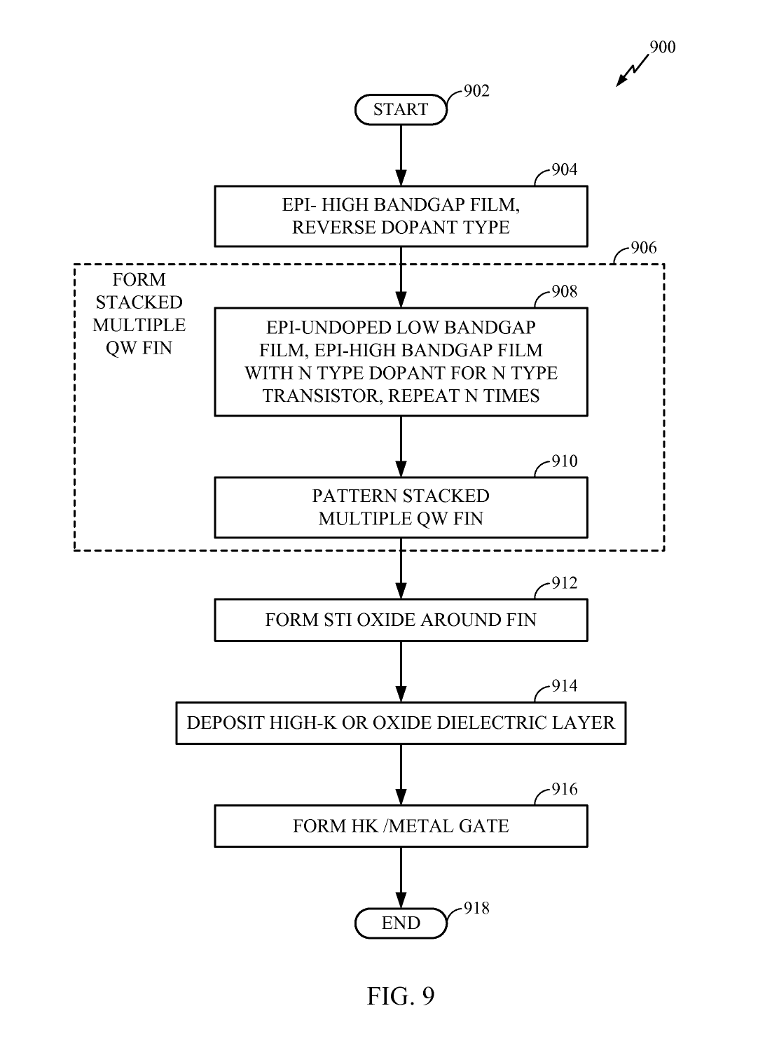

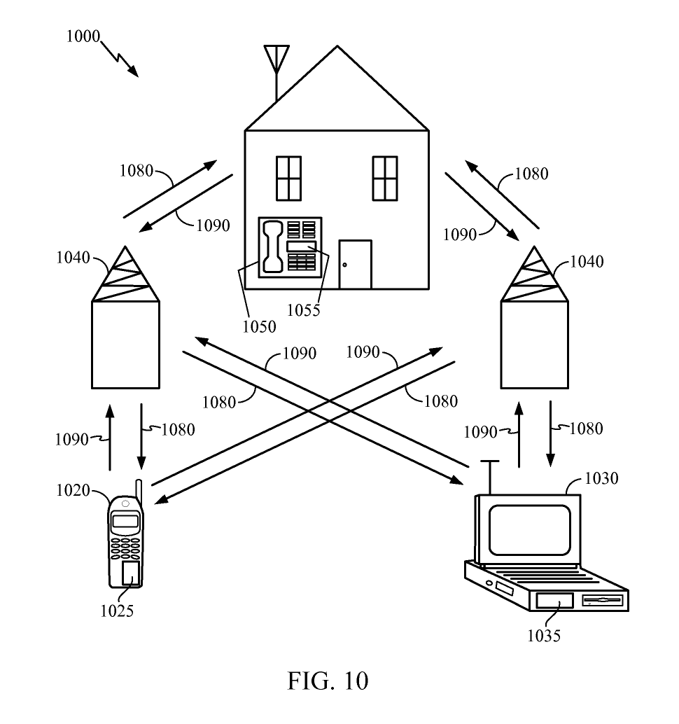

FIG. 9 shows one example flow of example operations 900 in one process of fabricating a stacked multiple 2DEG FET device according to various exemplary embodiments. To provide example structures illustrative of certain operations 900, it will be assumed the process is for fabricating toward the SM-2DEG device 400 of FIGS. 4A-4C. Reference is also made to the in-process structures of FIGS. 8A-8E.

Referring to FIG. 9, example operations 900 can start from an arbitrary start state 902 then, at 904, perform epitaxial growing of a high bandgap reverse dopant type film on a substrate. Referring to FIGS. 4A-4C, and 8A, examples of the epitaxial growing at 904 can include epitaxial growing the high bandgap reverse dopant type film for the HBG fin base 406 on the substrate 402, and epitaxial growing the high bandgap reverse dopant type film 804 on the substrate 402.

Referring to FIG. 9, example operations 900 can further include, at 906, a forming a stacked multiple QW fin. Referring to FIGS. 4A-4C and 8A-8E, the forming at 906 can be configured, for example, to form the SM QW fin 408 of FIGS. 4A-4C, or the SM QW fin 814 of FIG. 8C. Example operations in the forming at 906 can include, at 908, R repetitions of the following succession: epitaxial growing an undoped low bandgap film, followed by epitaxial growing, on the low bandgap film a high bandgap film having an N-type dopant. The undoped low bandgap film may also be referred to as an “undoped low bandgap layer.” The high bandgap film having an N-type dopant may also be referred to as a “high bandgap N-doped layer.” The result of the R repetitions can be a stack of 2R layers, comprising R undoped low bandgap layers interleaved with R high bandgap N-doped layers. The quantity R of the repetitions can be, for example, four, as shown in FIGS. 4A-4C and 8B. Operations in the forming, at 906, of a stacked multiple QW fin can include, at 910, patterning the stacked multiple QW fin from the stack of 2R layers formed at 908. Referring to FIGS. 8C and 9, the example operations in the patterning can be as described for the patterning of the MS QW fin 418.

Referring to FIG. 9, example operations 900 can include, after patterning the MS QW fin at 910 can include, at 912 an STI oxide layer around the MS QW fin. Referring to FIGS. 8C and 9, example operations in the forming at 912 of an STI oxide layer can be as described for the STI oxide layer 812. Example operations 900 can include, after the forming an STI oxide layer at 912, forming, at 914, a dielectric layer 820. Referring to FIGS. 8 and 9, the dielectric layer 820, which can be, for example, a high-K or normal oxide dielectric, can be one example of the dielectric layer formed at 914. Referring to FIGS. 7 and 9, example operations in the forming of an HK/metal gate at 916 can, for example, be in accordance with the example operations described for the forming at 718 of the HK/metal gate in the operations 700.

FIG. 10 illustrates an exemplary wireless communication system 1000 in which one or more embodiments of the disclosure may be advantageously employed. For purposes of illustration, FIG. 10 shows three remote units 1020, 1030, and 1050 and two base stations 1040. It will be recognized that conventional wireless communication systems may have many more remote units and base stations. The remote units 1020, 1030 and 1050 include integrated circuit or other semiconductor devices 325, 335 and 355 having, in various combinations, circuits embodying one or more of the MP2DEG device 100, MPQW device 200, MP2DEG-IF device 300, SM-2DEG device 400 and/or MV/SMH-2DEG device 500 described hereinabove, for example, as described in reference to FIGS. 1A-1C, 2, 3, 4A-4C and/or FIG. 5. FIG. 10 shows forward link signals 380 from the base stations 1040 and the remote units 1020, 1030, and 1050 and reverse link signals 390 from the remote units 1020, 1030, and 1050 to the base stations 1040.

In FIG. 10, the remote unit 1020 is shown as a mobile telephone, the remote unit 1030 is shown as a portable computer, and the remote unit 1050 is shown as a fixed location remote unit in a wireless local loop system. For example, the remote units may be any one or combination of a mobile phone, hand-held personal communication system (PCS) unit, portable data unit such as a personal data assistant (PDA), navigation device (such as GPS enabled devices), set top box, music player, video player, entertainment unit, fixed location data unit such as meter reading equipment, or any other device that stores or retrieves data or computer instructions, or any combination thereof. Although FIG. 10 illustrates remote units according to the teachings of the disclosure, the disclosure is not limited to these exemplary illustrated units. Embodiments of the disclosure may be suitably employed in any device having active integrated circuitry including various combinations, circuits embodying one or more of the MP2DEG device 100, MPQW device 200, MP2DEG-IF device 300, MPS-2DEG device 400 and/or MV/SMH-2DEG device 500 described hereinabove, for example, as described in reference to FIGS. 1A-1C, 2, 3, 4A-4C and/or FIG. 5.

The foregoing disclosed devices and functionalities may be designed and configured into computer files (e.g., RTL, GDSII, GERBER, etc.) stored on computer readable media. Some or all such files may be provided to fabrication handlers who fabricate devices based on such files. Resulting products include semiconductor wafers that are then cut into semiconductor die and packaged into a semiconductor chip. The chips are then employed in devices described above.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the embodiments disclosed herein may be implemented as electronic hardware, computer software, or combinations of both. To illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present invention.

The methods, sequences and/or algorithms described in connection with the embodiments disclosed herein may be embodied directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor.

While the foregoing disclosure shows illustrative embodiments of the invention, it should be noted that various changes and modifications could be made herein without departing from the scope of the invention as defined by the appended claims. The functions, steps and/or actions of the method claims in accordance with the embodiments of the invention described herein need not be performed in any particular order. Furthermore, although elements of the invention may be described or claimed in the singular, the plural is contemplated unless limitation to the singular is explicitly stated.

1. A multiple quantum well (QW) FinFET comprising
a fin base supported on a substrate, formed of a first material having a high bandgap;
an inner fin, formed of a second material having a high bandgap, having a first vertical face, and a second vertical face, wherein the second vertical face is spaced a fin thickness from and is parallel to the first vertical face; and
a carrier redistribution fin, formed of a third material having a low bandgap, surrounding the inner fin, wherein the carrier redistribution fin and the first vertical face have a first vertical planar interface, and the carrier redistribution fin and the first vertical face have a second vertical planar interface,
wherein the second material has a doping,
wherein the first material is reverse doped relative to the doping of the second material, and
wherein the third material has a low doping or is undoped.

2. The multiple QW FinFET of claim 1, wherein the doping of the first material is P-type and the doping of the second material is N-type, and wherein the third material has a low N-type doping or is undoped.

3. The multiple QW FinFET of claim 2 wherein the first material includes P-doped AlGaAs, P-doped AlAs, or P-doped GaAs, wherein the second material includes AlGaAs, AlAs, or GaAs, and wherein the third material includes undoped InGaAs, undoped InGaAsP, low N-doped InGaAs, or low N-doped InGaAsP.

4. The multiple QW FinFET of claim 3, further comprising a dielectric film, wherein the dielectric film is configured to surround the carrier redistribution fin.

5. The multiple QW FinFET of claim 4, wherein at least one of a bandgap of the first material and a bandgap of the second material, or a doping of the second material, or both, are configured to establish at least a first quantum well (QW) and, concurrent with the first QW, a second QW, wherein the first QW is in a first region of the carrier redistribution fin and the second QW is in a second region of the carrier redistribution fin, wherein the first region of the carrier redistribution fin is proximal to the first vertical planar interface, and wherein the second region is proximal to the second vertical planar interface.

6. The multiple QW FinFET of claim 5, wherein the inner fin includes a source region, a drain region, and a channel region, wherein the channel regions extends between the source region and the drain region,
wherein the first vertical planar interface and the second vertical planar interface extend in parallel from the source region to the drain region,
wherein an outer surface of the dielectric film includes a gate region, wherein the gate surrounds the channel region, and
wherein the multiple QW FinFET further comprises a conducting gate, wherein the conducting gate is configured to surround the gate region.

7. The multiple QW FinFET of claim 6, wherein the bandgap of the first material, the bandgap of the second material, a bandgap of the third material, or a doping of the first material, or a combination of two or more from among the bandgap of the first material, the bandgap of the second material, the bandgap of the third material, and the doping of the first material, are further configured to establish, in response to a ground reference voltage on the conducting gate, an equilibrium state, wherein the equilibrium state comprises a first two-dimensional electron gas in the first QW and a second two-dimensional electron gas in the second QW,
wherein a first ON channel is established by the first two-dimensional electron gas in the first QW,
wherein the first ON channel is between the source region and the drain region,
wherein a second ON channel is established by the second two-dimensional electron gas in the second QW, and
wherein the second ON channel is between the source region and the drain region, and the second ON channel is parallel with the first ON channel.

8. The multiple QW FinFET of claim 7, wherein the carrier redistribution fin, in response to a depletion voltage on the conducting gate, removes the first two-dimensional electron gas in the first QW, which removes the first ON channel, and removes the second two-dimensional electron gas in the second QW, which removes the second ON channel.

9. The multiple QW FinFET of claim 8, wherein the carrier redistribution fin, in response to switching from the depletion voltage conducting gate to the ground reference voltage on the conducting gate, redistributes charge to re-establish the first two-dimensional electron gas in the first QW and the second two-dimensional electron gas in the second QW, which re-establishes the first ON channel and the second ON channel.

10. The multiple QW FinFET of claim 9, wherein the inner fin further provides an inner fin top surface, and wherein the carrier redistribution fin and the inner fin top surface have a horizontal planar interface, wherein at least one of the bandgap of the first material and the bandgap of the second material, or the doping of the second material, or both, are further configured to establish a third QW, wherein the third QW is in a third region of the carrier redistribution fin, and wherein the third region of the carrier redistribution fin is proximal to the horizontal planar interface.

11. The multiple QW FinFET of claim 10, wherein the bandgap of the first material, the bandgap of the second material, the bandgap of the third material, or the doping of the first material, or a combination of two or more from among the bandgap of the first material, the bandgap of the second material, the bandgap of the third material, establish the equilibrium state to further comprise a third two-dimensional electron gas, wherein the third two-dimensional electron gas is concurrent with the first two-dimensional electron gas and the two-dimensional electron gas,
wherein the third two-dimensional electron gas establishes a third ON channel,
wherein the third ON channel extends between the source region and the drain region, and
wherein the third ON channel is concurrent with the first ON channel and the second ON channel.

12. The multiple QW FinFET of claim 11, wherein the carrier redistribution fin, in response to the depletion voltage on the conducting gate, removes the third two-dimensional electron gas, which removes the third ON channel, and
wherein the carrier redistribution fin, in response to switching from the depletion voltage on the conducting gate to the ground reference voltage on the conducting gate, further redistributes charge to re-establish, in the third QW, the third two-dimensional electron gas, which re-establishes the third ON channel.

13. A multiple two-dimensional electron gas quantum well FinFET device, comprising:
a fin base, wherein the fin base is supported on a substrate, wherein the fin base is formed of a first material, and wherein the first material has a high bandgap; and
a fin, wherein the fin is on the fin base, the fin comprising
an interleaved stack of 2R strips, R being an integer, wherein the interleaved stack of 2R strips comprises R low bandgap strips and R high bandgap strips, wherein the R low bandgap strips and the R high bandgap strips are arranged in an alternating stacking order, wherein each of the R low bandgap strips has an upper surface and a lower surface, wherein the upper surface forms an upper low bandgap—high bandgap planar interface with a bottom surface of a corresponding one of the R high bandgap strips, and the lower surface forms a lower low bandgap—high bandgap planar interface with a top surface of the fin base or with a top surface of a corresponding another of the R high bandgap strips.

14. The multiple two-dimensional electron gas quantum well FinFET device of claim 13, wherein a difference between a bandgap of the low bandgap strips and a bandgap of the high bandgap strips is set to establish within each of the low bandgap strips an upper quantum well and a lower quantum well,
wherein the upper quantum well is proximal to the upper surface and the lower quantum well is proximal to the lower surface.

15. The multiple two-dimensional electron gas quantum well FinFET device of claim 14, wherein the fin has a channel region, and wherein the multiple two-dimensional electron gas quantum well FinFET device further comprises a dielectric film, wherein the dielectric film is arranged to surround at least an area of the channel region.

16. The multiple two-dimensional electron gas quantum well FinFET device of claim 15, wherein the fin includes a source region and a drain region, and wherein the channel region extends between the source region and the drain region,
wherein an outer surface of the dielectric film is a gate region, and
wherein the multiple two-dimensional electron gas quantum well FinFET device further comprises a conducting gate, wherein the conducting gate is configured to surround the gate region.

17. The multiple two-dimensional electron gas quantum well FinFET device of claim 16, wherein each of the R low bandgap strips is formed of InGaAs or InGaAsP, and wherein each of the R high bandgap strips is formed of AlGaAs, AlAs or GaAs.

18. The multiple two-dimensional electron gas quantum well FinFET device of claim 16, wherein the difference between the bandgap of the low bandgap strips and the bandgap of the high bandgap strips is further set to establish, in response to a ground reference voltage on the conducting gate, an equilibrium state, wherein the equilibrium states comprises, in each of the R low bandgap strips, an upper two-dimensional electron gas and, concurrent with the upper two-dimensional electron gas, a lower two-dimensional electron gas, wherein the upper two-dimensional electron gas is in the upper quantum well and the lower two-dimensional electron gas is in the lower quantum well.

19. The multiple two-dimensional electron gas quantum well FinFET device of claim 18, wherein the difference between the bandgap of the low bandgap strips and the bandgap of the high bandgap strips is further set wherein the low bandgap strips, in response to a depletion voltage on the conducting gate, removes the upper two dimensional electron gas and removes the lower two-dimensional electron gas.

20. The multiple two-dimensional electron gas quantum well FinFET device of claim 19, wherein each of the low bandgap strips, in response to a switching from the depletion voltage on the conducting gate to the ground reference voltage on the conducting gate, redistribute carriers to re-establish, in the upper quantum well, the upper two-dimensional electron gas and concurrently re-establish, in the lower quantum well, the lower two-dimensional electron gas.

21. The multiple two-dimensional electron gas quantum well FinFET device of claim 13, wherein each of the low bandgap strips has a first thickness and each of the high bandgap strips has a second thickness,
wherein the first thickness, or the second thickness, or a difference between a bandgap of the low bandgap strips and a bandgap of the high bandgap strips, or any combination of two or more from among the first thickness, the second thickness, and the difference between the bandgap of the low bandgap strips and the bandgap of the high bandgap strips are set to establish within each of the low bandgap strips an upper quantum well and a lower quantum well, and
wherein the upper quantum well is proximal to the upper surface and the lower quantum well is proximal to the lower surface.

22. The multiple two-dimensional electron gas quantum well FinFET device of claim 21, wherein the fin has a channel region, wherein the multiple two-dimensional electron gas quantum well FinFET device further comprises a dielectric film, and wherein the dielectric film is arranged to surround at least a portion of the channel region,
wherein the fin includes a source region and a drain region, and wherein the channel region is arranged to extend between the source region and the drain region,
wherein a region of an outer surface of the dielectric film is a gate region, and
wherein the multiple two-dimensional electron gas quantum well FinFET device further comprises a conducting gate, and wherein the conducting gate is configured to surround the gate region.

23. The multiple two-dimensional electron gas quantum well FinFET device of claim 22, wherein the first thickness, or the second thickness, or the difference between the bandgap of the low bandgap strips and the bandgap of the high bandgap strips, or any combination of two or more from among the first thickness, the second thickness, and the difference between the bandgap of the low bandgap strips and the bandgap of the high bandgap strips are further set to establish, in response to a ground reference voltage on the conducting gate, an equilibrium state, wherein the equilibrium state comprises, in each of the R low bandgap strips, an upper two-dimensional electron gas and, concurrent with the upper two-dimensional electron gas, a lower two-dimensional electron, wherein the upper two-dimensional electron gas is in the upper quantum well and the lower two-dimensional electron gas is in the lower quantum well.

24. The multiple two-dimensional electron gas quantum well FinFET device of claim 23, wherein the first thickness, or the second thickness, or the difference between the bandgap of the low bandgap strips and the bandgap of the high bandgap strips, or any combination of two or more from among the first thickness, the second thickness, and the difference between the bandgap of the low bandgap strips and the bandgap of the high bandgap strips are further set wherein, in response to a depletion voltage on the conducting gate, the upper two-dimensional electron gas and the lower two-dimensional electron gas in each low bandgap strip is removed.

25. A method of fabricating a multiple quantum well device, comprising:
epitaxial growing a first high bandgap layer on a substrate;
epitaxial growing a second high bandgap layer on the first high bandgap layer;
patterning a fin from the second high bandgap layer on the first high bandgap layer, having a fin base, wherein the fin base comprises a portion of the first high bandgap layer;
forming a shallow trench isolation oxide surrounding the fin base;
epitaxial growing a low bandgap layer to cover a surface of the fin;
forming a dielectric film over a surface of the low bandgap layer; and
forming a conducting gate, wherein the conducting gate is formed over a gate region of the dielectric film.

26. The method of claim 25, wherein the first high bandgap layer includes P-doped AlGaAs, P-doped AlAs, undoped AlGaAs or undoped AlAs, and
wherein the low bandgap layer includes undoped InGaAs, undoped InGaAsP, low N-doped InGaAs, or low N-doped InGaAsP.

27. The method of claim 26, wherein patterning the fin forms an inner fin, wherein the inner fin has a first vertical face and a second vertical face, wherein the second vertical face is parallel to the first vertical face, and the inner fin has an inner fin top surface, and wherein epitaxial growing a low bandgap layer forms the low bandgap layer as a carrier redistribution fin, wherein the carrier redistribution fin has a planar interface with the first vertical face and a planar interface with the second vertical face.

28. The method of claim 27, wherein the dielectric film is a high-K dielectric film, and wherein the method further comprises forming, on the inner fin, a source region and a drain region.

29. A method of fabricating a multiple quantum well device, comprising:
epitaxial growing, on a substrate, a high bandgap reverse dopant film;
forming a stacked multiple quantum well fin on the high bandgap reverse dopant film, wherein said forming comprises
epitaxial growing a low bandgap undoped layer,
epitaxial growing, on the low bandgap undoped layer, a high bandgap N-doped layer,
repeating the epitaxial growing a low bandgap undoped layer, and the epitaxial growing a high bandgap N-doped layer R times to form a stack of 2R layers, wherein the stack of 2R layers comprises, in an interleaved alternating order, R low bandgap undoped layers and R high bandgap N-doped layers, and
patterning, from the stack of 2R layers, the stacked multiple quantum well fin;
forming, around the stacked multiple quantum well fin, a silicon trench isolation oxide;
depositing, over the stacked multiple quantum well fin, a dielectric layer; and
forming, over a gate region of the dielectric layer, an HK/metal gate.

30. The method of claim 29, wherein each of the R low bandgap undoped layers is formed of InGaAs or InGaAsP, and each of the R high bandgap N-doped layers is formed of AlGaAs, AlAs or GaAs.
